(19) United States
(12) Patent Application Publication
(10) Pub. No.: US 2024/0332461 A1
(43) Pub. Date: Oct. 3, 2024

(54) METHOD FOR MANUFACTURING LIGHT-EMITTING DEVICE, AND LIGHT-EMITTING DEVICE

(71) Applicant: NICHIA CORPORATION, Anan-shi (JP)

(72) Inventor: Takanobu SOGAI, Anan-shi (JP)

(73) Assignee: NICHIA CORPORATION, Anan-shi (JP)

(21) Appl. No.: 18/595,540

(22) Filed: Mar. 5, 2024

(30) Foreign Application Priority Data
Mar. 28, 2023 (JP) 2023-051372
Jul. 21, 2023 (JP) 2023-119144

(51) Int. Cl. H01L 33/50; H01L 25/075; H01L 33/00; H01L 33/58

(52) U.S. Cl. CPC H01L 33/50; H01L 25/0753; H01L 33/0095; H01L 33/58

(57) ABSTRACT

A method for manufacturing a light-emitting device includes providing a light-transmissive sheet that includes a light diffusion layer including a first resin portion and a light diffusion substance and a wavelength conversion layer disposed on the light diffusion layer and including a second resin portion in a stage B state and a wavelength conversion substance; performing a first heat treatment on the wavelength conversion layer; dividing an upper surface of the wavelength conversion layer into element arrangement regions by forming a first slit extending from the upper surface of the wavelength conversion layer, passing an interface between the wavelength conversion layer and the light diffusion layer, and reaching the light diffusion layer; disposing a light-emitting element in each of the element arrangement regions; performing a second heat treatment on the wavelength conversion layer; and disposing a covering member between the light-emitting elements and in the first slit.

### CROSS-REFERENCE TO RELATED APPLICATION

This application claims priority to Japanese Patent Application No. 2023-051372, filed on Mar. 28, 2023, and Japanese Patent Application No. 2023-119144, filed on Jul. 21, 2023, the disclosures of which are hereby incorporated by reference in their entireties.

### TECHNICAL FIELD

The present disclosure relates to a method for manufacturing a light-emitting device and to a light-emitting device.

### BACKGROUND

A light-emitting device is known that is obtained by disposing a light-emitting element on a wavelength conversion layer via a liquid adhesive, curing the liquid adhesive, and then disposing a light-reflecting member on a lateral surface of the light-emitting element. In such a light-emitting device, in a case in which a plurality of light-emitting elements are disposed on the wavelength conversion layer, with a decrease in a separation distance between the light-emitting elements, the liquid adhesive may run into the space between adjacent light-emitting elements, inhibiting a light-reflecting member from being sufficiently disposed in the space between the light-emitting elements in the process of disposing the light-reflecting member, in some cases. As a result, there is a possibility that the light-emitting characteristics of the light-emitting device deteriorate (see, for example, Japanese Patent Publication No. 2020-098906).

### SUMMARY

An object of certain embodiments of the present disclosure is to provide a method for manufacturing a light-emitting device with good light-emitting characteristics, and such a light-emitting device.

A method for manufacturing a light-emitting device according to an aspect of the present disclosure includes: providing a light-transmissive sheet that includes a light diffusion layer including a first resin portion and a light diffusion substance and a wavelength conversion layer disposed on the light diffusion layer and including a second resin portion in a stage B state and a wavelength conversion substance; performing a first heat treatment on the wavelength conversion layer under a first condition to increase a hardness of the wavelength conversion layer; subsequent to the first heat treatment, dividing an upper surface of the wavelength conversion layer into a plurality of element arrangement regions by forming a first slit extending from the upper surface of the wavelength conversion layer, passing an interface between the wavelength conversion layer and the light diffusion layer, and reaching the light diffusion layer; disposing a light-emitting element in each of the plurality of element arrangement regions by bringing a light-emitting surface of the light-emitting element into contact with the upper surface of the wavelength conversion layer; subsequent to the disposing of the light-emitting element, performing a second heat treatment on the wavelength conversion layer under a second condition to cure the wavelength conversion layer; and subsequent to the second heat treatment, disposing a covering member between a plurality of the light-emitting elements and in the first slit.

A light-emitting device according to an aspect of the present disclosure includes: a plurality of light-emitting portions each including a light-emitting element and a light-transmissive member including a wavelength conversion layer directly disposed on the light-emitting element; and a covering member disposed between adjacent light-emitting elements of a plurality of the light-emitting elements and between adjacent light-transmissive members of a plurality of the light-transmissive members. In the light-emitting device, the wavelength conversion layer has a first surface where the light-emitting element is disposed, a second surface located on a side opposite to the first surface, and a lateral surface connecting the first surface and the second surface, the lateral surface is inclined to form an obtuse angle with the first surface and an acute angle with the second surface, and a corner portion formed between the first surface and the lateral surface is a curved surface.

A method for manufacturing a light-emitting device according to an aspect of the present disclosure includes: providing a light-transmissive sheet that includes a light diffusion layer including a first resin portion and a light diffusion substance and a wavelength conversion layer disposed on the light diffusion layer and including a second resin portion and a wavelength conversion substance; disposing an adhesive resin layer in a stage B state on an upper surface of the wavelength conversion layer; dividing an upper surface of the adhesive resin layer into a plurality of element arrangement regions by forming a slit extending from an upper surface of the adhesive resin layer and reaching the light diffusion layer; disposing a light-emitting element in each of the plurality of element arrangement regions by bringing a light-emitting surface of the light-emitting element into contact with the upper surface of the adhesive resin layer; subsequent to the disposing of the light-emitting element, performing a heat treatment on the adhesive resin layer to cure the adhesive resin layer; and subsequent to the heat treatment, disposing a covering member between a plurality of the light-emitting elements and in the slit. In the method for manufacturing a light-emitting device, the forming of the slit includes forming a first slit, the first slit including a first opening at the upper surface of the adhesive resin layer and a first bottom portion, and forming a second slit, the second slit including a second opening at the first bottom portion, having a width smaller than a width of the first slit, and extending into the light diffusion layer.

A light-emitting device according to an aspect of the present disclosure includes: a plurality of light-emitting portions each including a light-emitting element, an adhesive resin layer disposed on the light-emitting element, and a light-transmissive member disposed on the adhesive resin layer, the light-transmissive member including a wavelength conversion layer including a wavelength conversion substance and a light-transmissive intermediate layer not including a wavelength conversion substance; and a covering member disposed between adjacent light-emitting elements of a plurality of the light-emitting elements and between adjacent light-transmissive members of a plurality of the light-transmissive members. In the light-emitting device, the light-transmissive member has a first primary surface that is in contact with the adhesive resin layer, a second primary surface located on a side opposite to the first primary surface, a first lateral surface continuous with the first primary surface, a second lateral surface continuous with the second primary surface, and an intermediate surface located in the light-transmissive intermediate layer and connecting the first lateral surface and the second lateral surface, and a first width of the covering member disposed between the first lateral surfaces of adjacent light-transmissive members of the plurality of light-transmissive members is greater than a second width of the covering member disposed between the second lateral surfaces of the adjacent light-transmissive members.

According to certain embodiments of the present disclosure, a method for manufacturing a light-emitting device with good light-emitting characteristics and a light-emitting device can be provided.

### BRIEF DESCRIPTION OF DRAWINGS

FIG. 1 is a schematic top view of a light-emitting device according to a first embodiment.

FIG. 2 is a schematic cross-sectional view taken along line II-II of FIG. 1.

FIG. 3 is a schematic cross-sectional view of a first modified example of the light-emitting device according to the first embodiment.

FIG. 4 is a schematic cross-sectional view of a second modified example of the light-emitting device according to the first embodiment.

FIG. 5A is a schematic top view for explaining a process of a method for manufacturing the light-emitting device according to the first embodiment.

FIG. 5B is a schematic cross-sectional view taken along line VB-VB of FIG. 5A.

FIG. 5C is a schematic top view for explaining a process of the method for manufacturing the light-emitting device according to the first embodiment.

FIG. 5D is a schematic cross-sectional view taken along line VD-VD of FIG. 5C.

FIG. 5E is a schematic top view for explaining a process of the method for manufacturing the light-emitting device according to the first embodiment.

FIG. 5F is a schematic cross-sectional view taken along line VF-VF of FIG. 5E.

FIG. 5G is a schematic cross-sectional view for explaining a process of the method for manufacturing the light-emitting device according to the first embodiment.

FIG. 5H is a schematic cross-sectional view for explaining a process of the method for manufacturing the light-emitting device according to the first embodiment.

FIG. 6A is a schematic cross-sectional view for explaining a process of a method for manufacturing a third modified example of the light-emitting device according to the first embodiment.

FIG. 6B is a schematic cross-sectional view for explaining a process of the method for manufacturing the third modified example of the light-emitting device according to the first embodiment.

FIG. 7 is a schematic cross-sectional view illustrating a light-emitting device according to a second embodiment.

FIG. 8A is a schematic cross-sectional view for explaining a process of a method for manufacturing the light-emitting device according to the second embodiment.

FIG. 8B is a schematic cross-sectional view for explaining a process of the method for manufacturing the light-emitting device according to the second embodiment.

FIG. 8C is a schematic cross-sectional view for explaining a process of the method for manufacturing the light-emitting device according to the second embodiment.

FIG. 8D is a schematic cross-sectional view for explaining a process of the method for manufacturing the light-emitting device according to the second embodiment.

FIG. 8E is a schematic cross-sectional view for explaining a process of the method for manufacturing the light-emitting device according to the second embodiment.

FIG. 8F is a schematic cross-sectional view for explaining a process of the method for manufacturing the light-emitting device according to the second embodiment.

FIG. 8G is a schematic cross-sectional view for explaining a process of the method for manufacturing the light-emitting device according to the second embodiment.

FIG. 9 is a schematic cross-sectional view of a light-emitting device according to a third embodiment.

FIG. 10A is a schematic cross-sectional view for explaining a process of a method for manufacturing the light-emitting device according to the third embodiment.

FIG. 10B is a schematic cross-sectional view for explaining a process of the method for manufacturing the light-emitting device according to the third embodiment.

FIG. 10C is a schematic cross-sectional view for explaining a process of the method for manufacturing the light-emitting device according to the third embodiment.

FIG. 10D is a schematic cross-sectional view for explaining a process of the method for manufacturing the light-emitting device according to the third embodiment.

FIG. 10E is a schematic cross-sectional view for explaining a process of the method for manufacturing the light-emitting device according to the third embodiment.

FIG. 10F is a schematic cross-sectional view for explaining a process of the method for manufacturing the light-emitting device according to the third embodiment.

FIG. 10G is a schematic cross-sectional view for explaining a process of the method for manufacturing the light-emitting device according to the third embodiment.

FIG. 11A is a schematic top view of a light-emitting device according to a fourth embodiment.

FIG. 11B is a schematic cross-sectional view taken along line XIB-XIB of FIG. 11A.

FIG. 11C is a schematic cross-sectional view of a modified example of the light-emitting device according to the fourth embodiment.

FIG. 12A is a schematic cross-sectional view for explaining a process of a method for manufacturing the light-emitting device according to the fourth embodiment.

FIG. 12B is a schematic cross-sectional view for explaining a process of the method for manufacturing the light-emitting device according to the fourth embodiment.

FIG. 12C is a schematic cross-sectional view for explaining a process of the method for manufacturing the light-emitting device according to the fourth embodiment.

FIG. 12D is a schematic cross-sectional view for explaining a process of the method for manufacturing the light-emitting device according to the fourth embodiment.

FIG. 12E is a schematic cross-sectional view for explaining a process of the method for manufacturing the light-emitting device according to the fourth embodiment.

FIG. 12F is a schematic cross-sectional view for explaining a process of the method for manufacturing the light-emitting device according to the fourth embodiment.

FIG. 12G is a schematic cross-sectional view for explaining a process of the method for manufacturing the light-emitting device according to the fourth embodiment.

FIG. 12H is a schematic cross-sectional view for explaining a process of the method for manufacturing the light-emitting device according to the fourth embodiment.

### DETAILED DESCRIPTIONS

A method for manufacturing a light-emitting device and a light-emitting device according to embodiments of the present disclosure will be described below with reference to the drawings. The following embodiments are examples of a method for manufacturing a light-emitting device and a light-emitting device embodying technical concepts of the invention, but the invention is not limited to the embodiments described below. Further, dimensions, materials, shapes, relative arrangements, or the like of constituent members described in the embodiments are not intended to limit the scope of the present disclosure thereto, unless otherwise specified, and are merely exemplary. Note that the sizes, positional relationship, or the like of members illustrated in each of the drawings may be exaggerated for clarity of description. Further, in the following description, members having the same terms and reference characters represent the same or similar members, and a repeated detailed description of these members will be omitted as appropriate. As a cross-sectional view, an end view illustrating only a cut surface may be illustrated.

In the following description, terms indicating specific directions or positions (for example, “upper/upward,” “lower/downward,” and other terms including or related to those terms) may be used. However, these terms are used merely to make it easy to understand relative directions or positions in the referenced drawing. As long as the relative direction or position is the same as that described in the referenced drawing using the term such as “upper/upward” or “lower/downward,” in drawings other than the drawings of the present disclosure, actual products, and the like, components need not be arranged in the same manner as that in the referenced drawing. For example, on the assumption that there are two members, the positional relationship expressed as “upper (or lower)” in the present specification may include a case in which the two members are in contact with each other and a case in which the two members are not in contact with each other and one of the two members is located above (or below) the other member. Further, in the present specification, unless otherwise specified, a case in which a member covers an object to be covered includes a case in which the member is in contact with the object to be covered and directly covers the object to be covered, and a case in which the member is not in contact with the object to be covered and indirectly covers the object to be covered. Further, in the present specification, a width, a distance, and a thickness of a member in a specific direction respectively represent maximum values of the width, the distance, and the thickness in the specific direction.

In the following drawings, directions may be indicated by an X-axis, a Y-axis, and a Z-axis. An X direction along the X-axis indicates a predetermined direction in a light-emitting surface of a light-emitting device according to an embodiment. AY direction along the Y-axis indicates a direction orthogonal to the X direction in the light-emitting surface. AZ direction along the Z-axis indicates a direction orthogonal to the above-described light-emitting surface. In other words, the light-emitting surface of the light-emitting device is parallel to an XY plane, and the Z-axis is orthogonal to the XY plane.

In the present specification, the following terms defined by the JISK6800 standard are used as terms indicating the cured states of resins.
Stage A: Initial state of thermosetting resin forming reaction. A resin in this state is still soluble in certain solvents and melts when heated.
Stage B: Intermediate cured state of the thermosetting resin. A resin in this state softens when heated and swells when brought into contact with certain solvents but does not completely melt or dissolve.
Stage C: Final state of the curing reaction of the thermosetting resin. A resin in this state is insoluble and infusible, and a thermosetting resin in a completely cured adhesive layer is in this state.

### First Embodiment

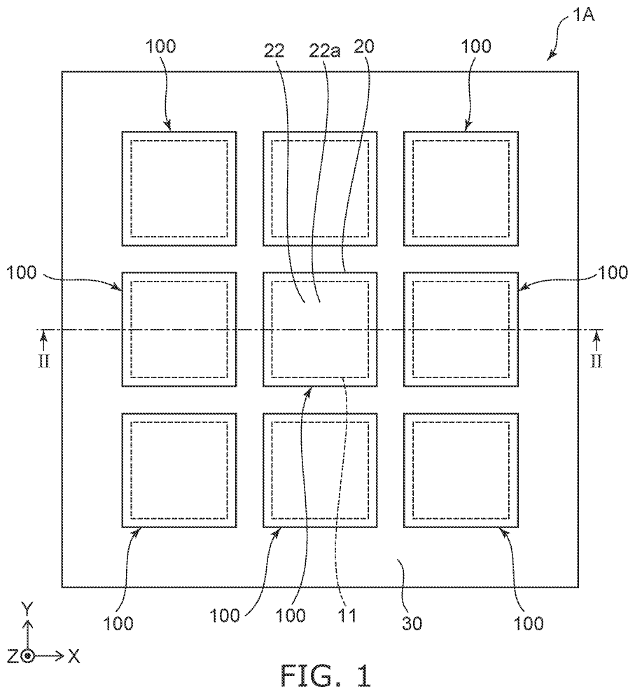

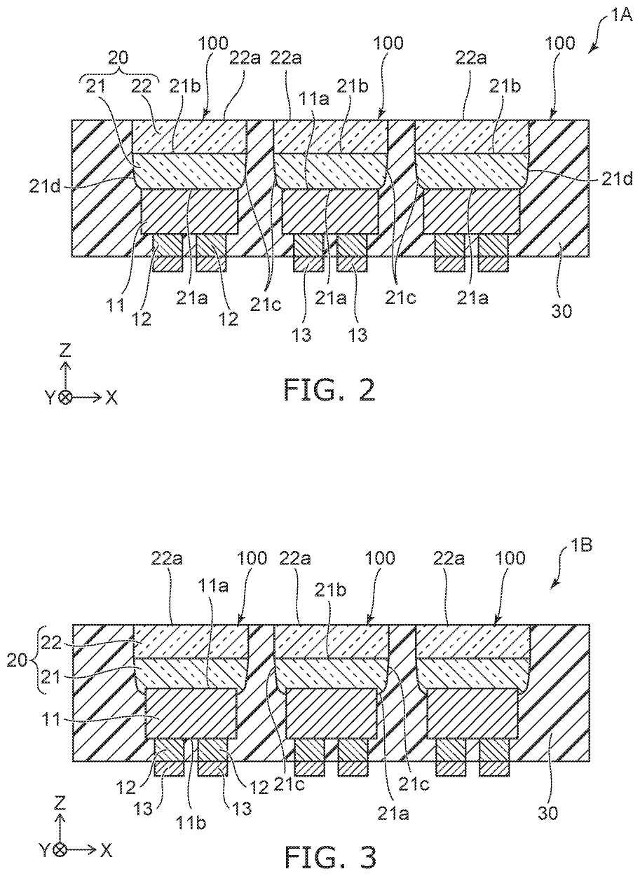

A light-emitting device 1A according to a first embodiment will be described with reference to FIGS. 1 and 2. In a top view, one direction in the light-emitting surface of the light-emitting device 1A, such as a direction along the X-axis, for example, is defined as a first direction X. A direction intersecting the first direction X in the light-emitting surface of the light-emitting device 1A, such as a direction along the Y-axis, for example, is defined as a second direction Y A direction orthogonal to the light-emitting surface of the light-emitting device 1A and along the Z-axis, for example, is defined as a third direction Z. The first direction, the second direction, and the third direction need not be a direction along the X-axis, the Y-axis, and the Z-axis, respectively.

The light-emitting device 1A is provided with a plurality of light-emitting portions 100 and a covering member 30. In FIG. 1, nine light-emitting portions 100 are illustrated, but the number of the light-emitting portions 100 is not limited to this number. Three light-emitting portions 100 adjacent to each other in the first direction X are illustrated in FIG. 2.

The light-emitting device 1A can be used as a flash light source for an imaging device, for example. The imaging device can be mounted on, for example, a mobile communication terminal. When the light-emitting device 1A is used as the flash light source for the imaging device, for example, light can be emitted by switching between a narrow-angle mode in which only the light-emitting portions 100 disposed centrally in a top view emit light and a wide-angle mode in which all of the light-emitting portions 100 emit light. In the narrow-angle mode, a light emission angle is narrower than in the wide-angle mode. Because the light-emitting device 1A can switch the emission light in accordance with the narrow-angle mode and the wide-angle mode, photography according to a photography mode in an imaging device, such as telescopic photography or close-up photography, is possible, for example.

### Light-Emitting Portion

Each of the light-emitting portions 100 includes a light-emitting element 11 and a light-transmissive member 20.

### Light-Emitting Element

The light-emitting element 11 includes a semiconductor structure body and an element electrode. The semiconductor structure body includes a nitride semiconductor. In the present specification, it is assumed that examples of the nitride semiconductor include semiconductors having all compositions of a chemical formula expressed by InₓAl_{y}Ga_{1-x-y}N (0≤x≤1, 0≤y≤1, x+y≤1) in which the composition ratios of x and y are changed within the respective ranges. Further, it is assumed that examples of the nitride semiconductor also include a semiconductor further containing a group V element other than nitrogen (N) in the chemical formula described above, and a semiconductor further containing, in the chemical formula described above, various elements added to control various physical properties such as the conductivity type of the semiconductor. The semiconductor structure body includes an active layer. The active layer is a light-emitting layer that emits light and has a multiple quantum well (MQW) structure body including a plurality of barrier layers and a plurality of well layers, for example. Light emitted by the active layer is visible light or ultraviolet light, for example. For example, a plurality of the light-emitting elements 11 in which variations in optical characteristics (luminance, chromaticity, and the like) fall within a predetermined range are selected and used in the light-emitting device 1A. The semiconductor structure body may further include a protective film that protects the semiconductor.

The light-emitting element 11 has a light-emitting surface 11a that comes into direct contact with the light-transmissive member 20. The light-emitting element 11 may further include a support substrate, such as a silicon substrate or a sapphire substrate, which supports the semiconductor structure body. In this case, the light-emitting surface 11a of the light-emitting element 11 is a surface of the support substrate on the side opposite to the semiconductor structure body. Also, the light-emitting element 11 need not include the support substrate. In this case, the light-emitting surface 11a of the light-emitting element 11 is a surface of the semiconductor structure body on the side opposite to the surface at which the element electrode is formed. In this case, the light-transmissive member 20 and the semiconductor structure body are in direct contact with each other.

### Light-Transmissive Member

For example, the light-transmissive member 20 has light transmissivity with respect to the light emitted by the light-emitting element 11. The transmittance of the light-transmissive member 20 with respect to the light emission peak wavelength of the light-emitting element 11 is 70% or greater, preferably 80% or greater, and more preferably 90% or greater. The light-emitting surface of the light-emitting device 1A includes upper surfaces of the light-transmissive members 20. As illustrated in FIG. 1, in a top view, an outer edge (indicated by a solid line) of the light-transmissive member 20 is located outward of an outer edge (indicated by a dashed line) of the light-emitting element 11. Thus, the light emitted from the light-emitting element 11 is efficiently incident on the light-transmissive member 20.

The light-transmissive member 20 includes at least a wavelength conversion layer 21. The wavelength conversion layer 21 includes a second resin portion, and a wavelength conversion substance that is contained in the second resin portion and converts the wavelength of at least part of the light emitted by the light-emitting element 11. The wavelength conversion layer 21 is disposed directly on the light-emitting element 11. The wavelength conversion layer 21 has a first surface 21a that is in direct contact with the light-emitting surface 11a of the light-emitting element 11. In other words, the light-emitting surface 11a of the light-emitting element 11 is joined in direct contact with the first surface 21a of the wavelength conversion layer 21. In the light-emitting device 1A according to the first embodiment, no adhesive is disposed between the light-emitting surface 11a of the light-emitting element 11 and the first surface 21a of the wavelength conversion layer 21.

No adhesive is disposed between the light-emitting surface 11a of the light-emitting element 11 and the first surface 21a of the wavelength conversion layer 21, and the light-emitting element 11 and the wavelength conversion layer 21 are in direct contact with each other. This can reduce light absorption by the adhesive, light reflection at the interface between the light-emitting element 11 and the adhesive, and light reflection at the interface between the adhesive and the wavelength conversion layer 21. Thus, the extraction efficiency of light from the light-emitting surfaces of the light-emitting portions 100 can be improved. In addition, because no adhesive is disposed between the light-emitting element 11 and the wavelength conversion layer 21, it is possible to reduce the thickness of the light-emitting portion 100. In addition, in the manufacturing process described below, by using no adhesive, an uncured adhesive can be suppressed from entering between adjacent light-emitting portions 100, and the covering member 30 can be easily disposed between adjacent light-emitting portions 100 in the process of disposing the covering member 30. As a result, a light-emitting device with good light-emitting characteristics can be manufactured.

As the material of the second resin portion of the wavelength conversion layer 21, a thermosetting resin, such as a silicone resin, a modified silicone resin, an epoxy resin, a modified epoxy resin, a phenol resin, or the like can be used. From among these, particularly, a silicone resin or a modified silicone resin with good light resistance and heat resistance is preferably used.

As the wavelength conversion substance, for example, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI quantum dot (for example, CdSe), a III-V quantum dot (for example, InP), a quantum dot having a chalcopyrite structure (for example, (Ag,Cu)(In,Ga)(S,Se)₂), or the like can be used.

The wavelength conversion layer 21 may include one type of wavelength conversion substance or may include a plurality of types of wavelength conversion substances. For example, the light-emitting portion 100 emits mixed light including light emitted by the light-emitting element 11 and light emitted by the wavelength conversion substance of the wavelength conversion layer 21 via excitation by light emitted by the light-emitting element 11. The plurality of light-emitting portions 100 may be composed of the light-emitting portions 100 having the same light emission peak wavelength or may be composed of the light-emitting portions 100 having different light emission peak wavelengths.

The wavelength conversion layer 21 has the first surface 21a that is in contact with the light-emitting element 11, a second surface 21b that is located on the side opposite to the first surface 21a and is provided with a light diffusion layer 22 described below, and a lateral surface 21c that connects the first surface 21a and the second surface 21b. The lateral surface 21c is a lateral surface facing a lateral surface of an adjacent wavelength conversion layer 21.

In the light-emitting device 1A, the lateral surface 21c of the wavelength conversion layer 21 is inclined so as to form an obtuse angle with the first surface 21a and an acute angle with the second surface 21b. The lateral surface 21c is inclined such that, with respect to adjacent wavelength conversion layers 21, the distance between the first surfaces 21a is greater than the distance between the second surfaces 21b. Because the lateral surface 21c of the wavelength conversion layer 21 is inclined in this manner, the light emitted from the light-emitting surface 11a of the light-emitting element 11 can be easily reflected upward (toward the light-emitting surface of the light-emitting portion 100) at the lateral surface 21c of the wavelength conversion layer 21. Thus, the extraction efficiency of light from the light-emitting surfaces of the light-emitting portions 100 can be improved.

In addition, the corner portion formed between the first surface 21a and the lateral surface 21c of the wavelength conversion layer 21 is a curved surface. The corner portion formed between the second surface 21b and the lateral surface 21c of the wavelength conversion layer 21 is not a curved surface. Because the corner portion formed between the first surface 21a and the lateral surface 21c of the wavelength conversion layer 21 is a curved surface, light confinement in the wavelength conversion layer 21 can be suppressed and the extraction efficiency of light from the light-emitting surface of the light-emitting portion 100 can be improved.

In addition, the lateral surface 21d of the wavelength conversion layer 21 located at the outermost periphery in a top view which is not adjacent to another wavelength conversion layer 21 is also inclined so as to form an obtuse angle with the first surface 21a and an acute angle with the second surface 21b, and the corner portion formed between the first surface 21a and the lateral surface 21d is a curved surface. Thus, in a similar manner, the extraction efficiency of light from the light-emitting surfaces of the light-emitting portions 100 can be improved. In addition, the covering property of the covering member 30 is improved at the corner portion of the wavelength conversion layer 21 on the light-emitting element 11 side, and the light propagation to the adjacent light-emitting portion 100 is reduced by the covering member 30, so that high contrast can be achieved.

The light-transmissive member 20 may further include the light diffusion layer 22. The light diffusion layer 22 is disposed on the second surface 21b located on the side opposite to the first surface 21a of the wavelength conversion layer 21. In this case, an upper surface 22a of the light diffusion layer 22 constitutes the upper surface of the light-transmissive member 20.

In the present embodiment, the light diffusion layers 22 of the light-emitting portions 100 are separated from each other in the first direction X and the second direction Y Note that the present disclosure is not limited to this configuration, and for example, one light diffusion layer 22 may be disposed across all of the light-emitting elements 11. In that case, the light emitted from the plurality of light-emitting portions 100 can be diffused by the light diffusion layer 22 located on the light-emitting surface side of the light-emitting device 1A, and luminance unevenness and chromaticity unevenness of the light-emitting device 1A can be reduced.

The light diffusion layer 22 includes a first resin portion and a light diffusion substance that is contained in the first resin portion and diffuses the light emitted by the light-emitting element 11. As the material of the first resin portion of the light diffusion layer 22, a material the same as or similar to the material of the second resin portion of the wavelength conversion layer 21 can be used. As the light diffusion substance, titanium oxide, silicon oxide, or the like can be used.

### Covering Member

The covering member 30 is disposed between adjacent light-emitting elements 11 of the plurality of light-emitting elements 11 and between adjacent light-transmissive members 20 of the plurality of light-transmissive members 20 and collectively holds the plurality of light-emitting portions 100. The covering member 30 covers the element lateral surface of the light-emitting element 11 and the lateral surface of the light-transmissive member 20. A light-emitting surface of the light-emitting portion 100 (in this example, the upper surface 22a of the light diffusion layer 22) is exposed from the covering member 30.

The transmittance of the covering member 30 with respect to the light emission peak wavelength of the light-emitting element 11 is lower than the transmittance of the light-transmissive member 20 with respect to the light emission peak wavelength of the light-emitting element 11. The transmittance of the covering member 30 with respect to the light emission peak wavelength of the light-emitting element 11 is 20% or less, and preferably 10% or less, for example. Also, the covering member 30 has insulating properties.

In a case in which one light-emitting portion 100 emits light and another light-emitting portion 100 adjacent thereto does not emit light, light emitted by the light-emitting portion 100 may be incident on the light-transmissive member 20 of the adjacent light-emitting portion 100 which does not emit light. This may cause light emission from the wavelength conversion substance contained in the light-transmissive member 20 of the light-emitting portion 100 which does not emit light. However, the covering member 30 is provided between adjacent light-emitting elements 11 and between adjacent light-transmissive members 20, to thereby suppress light emission from the wavelength conversion substance contained in the light-transmissive member 20 of the light-emitting portion 100 which does not emit light. As a result, a light-emitting device 1A having a high contrast can be obtained.

In a top view, the covering member 30 is partially disposed in the outer peripheral portion of the light-emitting device 1A in addition to between adjacent light-emitting elements 11 and between adjacent light-transmissive members 20. Specifically, in a top view, the covering member 30 covers a lateral surface, not adjacent to any other light-emitting portion 100, of the outermost one of the light-transmissive members 20. Accordingly, it is possible to reduce light emission to a region outward of the light-transmissive member 20 located at the outermost periphery, and to increase the luminance difference, in the light-emitting surface of the light-emitting device 1A, between the upper surface of the light-transmissive member 20 and the upper surface of the covering member 30 located at the outer peripheral portion of the light-emitting device 1A, thus making it possible to achieve high contrast.

In a top view, the covering member 30 covers a lateral surface of one of the light-emitting elements 11 located at the outermost periphery which is not adjacent to another one of the light-emitting elements 11. Accordingly, it is possible to reduce light emission to a region outward of the light-emitting element 11 located at the outermost periphery, and to increase the luminance difference, in the light-emitting surface of the light-emitting device 1A, between the upper surface of the light-transmissive member 20 and the upper surface of the covering member 30 located at the outer peripheral portion of the light-emitting device 1A, thus making it possible to achieve high contrast.

It is preferable that the covering member 30 has light reflectivity and reflects the light emitted by the light-emitting portions 100, or has light absorptivity and absorbs the light emitted by the light-emitting portions 100. In particular, the covering member 30 preferably has light reflectivity with respect to the light emitted by the light-emitting portions 100. In this case, the light from the individual light-emitting portions 100 can be efficiently reflected by the covering member 30, and a luminous flux of the light-emitting device 1A is likely to increase.

The covering member 30 may include a fourth resin portion and an additive with light reflectivity or light absorptivity contained in the fourth resin portion. A material the same as or similar to the materials given as examples for the second resin portion described above can be used as the material of the fourth resin portion. A substance the same as or similar to the substances given as examples for the light diffusion substance described above can be used as the additive with light reflectivity. Carbon black or the like can be used as the additive with light absorptivity, for example.

The light-emitting portion 100 can further include electrodes 12. The electrodes 12 are disposed on a lower surface 11b of the light-emitting element 11 located on the side opposite to the light-emitting surface 11a and are electrically connected to the element electrode of the light-emitting element 11. Each of the light-emitting portions 100 includes two or more electrodes 12. The two or more electrodes 12 include an electrode functioning as an anode electrode and an electrode functioning as a cathode electrode. Note that the element electrode included in the light-emitting element 11 may also be used as the electrodes of the light-emitting portion 100.

The covering member 30 covers the lower surface 11b of the light-emitting element 11 and the lateral surfaces of the electrodes 12. The lower surfaces of the electrodes 12 are exposed from the covering member 30. The lower surfaces of the electrodes 12 are joined, via a joining member such as a solder, to a conductive portion disposed on a wiring substrate where the light-emitting device 1A is mounted. A metal film 13 may be disposed on the individual lower surfaces of the electrodes 12. For example, the metal film 13 includes a gold-containing film, and a nickel-containing film disposed between the gold-containing film and the individual lower surfaces of the electrodes 12. The gold-containing film in the metal film 13 protects the individual electrodes 12 from corrosion and oxidation. The nickel-containing film in the metal film 13 increases adhesion between each of the electrodes 12 and the gold-containing film.

### First Modified Example of First Embodiment

A light-emitting device 1B according to a first modified example of the first embodiment will be described with reference to FIG. 3.

In the light-emitting device 1i, the light-emitting surface 11a, which is a surface of the light-emitting element 11 that is in contact with the wavelength conversion layer 21, is embedded in the wavelength conversion layer 21. The wavelength conversion layer 21 covers the light-emitting surface 11a of the light-emitting element 11 and part of the lateral surface of the light-emitting element 11 on the light-emitting surface 11a side. In addition, the corner portion formed between the light-emitting surface 11a and the lateral surface of the light-emitting element 11 is embedded in the wavelength conversion layer 21. In such a configuration, the contact area between the light-emitting element 11 and the wavelength conversion layer 21 can be increased as compared with a configuration in which only the light-emitting surface 11a of the light-emitting element 11 is in contact with the wavelength conversion layer 21, and thus the adhesive strength between the light-emitting element 11 and the wavelength conversion layer 21 tends to be increased.

### Second Modified Example of First Embodiment

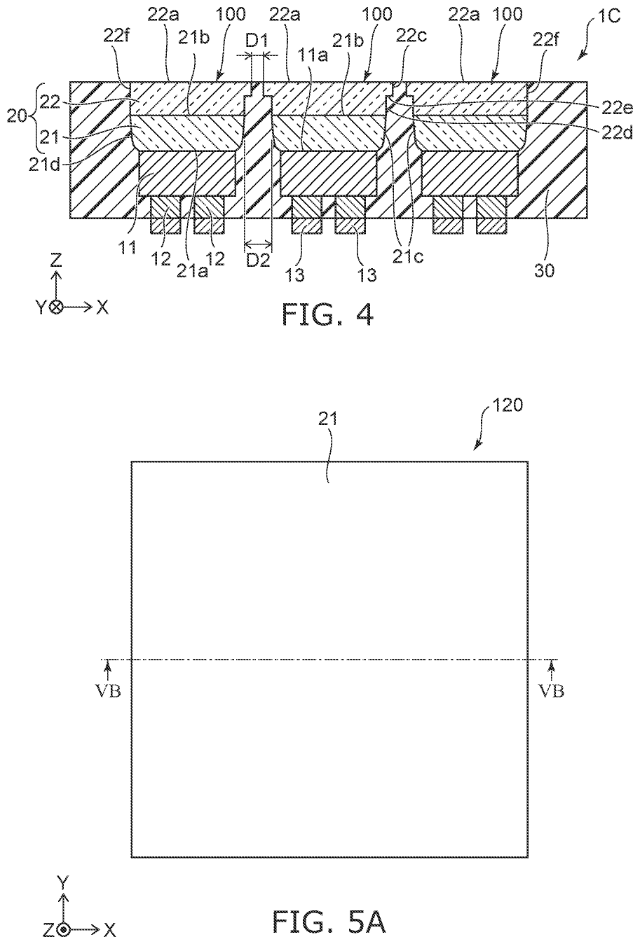

A light-emitting device 1C according to a second modified example of the first embodiment will be described with reference to FIG. 4.

In the light-emitting device 1C, a distance D1 between the upper surfaces 22a of adjacent ones of the light diffusion layers 22 is less than a distance D2 between the second surfaces 21b of adjacent ones of the wavelength conversion layers 21. By increasing the distance D2 between the second surfaces 21b of the adjacent wavelength conversion layers 21, it is possible to increase the width of the covering member 30 disposed between the wavelength conversion layers 21. This can suppress light from entering the wavelength conversion layers 21 from the light-emitting elements 11, and light that is wavelength-converted by the wavelength conversion layers 21 from entering the adjacent wavelength conversion layers 21. Accordingly, it is possible to achieve high contrast as described above due to the covering member 30 disposed between the adjacent wavelength conversion layers 21. On the other hand, by reducing the distance D1 between the upper surfaces 22a of the adjacent light diffusion layers 22, it is possible to increase the area of the light-emitting surface of each of the light-emitting portions 100. Thus, light extraction efficiency of the light-emitting device 1C can be improved. The distance between the upper surfaces 22a of the adjacent light diffusion layers 22 is, for example, in a range from 10 μm to 30 μm.

In the example illustrated in FIG. 4, the light diffusion layer 22 has a first lateral surface 22c continuous with the upper surface 22a, a second lateral surface 22d continuous with the lateral surface 21c of the wavelength conversion layer 21, and an intermediate surface 22e located between the first lateral surface 22c and the second lateral surface 22d and continuous with the first lateral surface 22c and the second lateral surface 22d. The distance between the first lateral surfaces 22c of the adjacent light diffusion layers 22 is substantially equal to the distance D1 between the upper surfaces 22a of the adjacent light diffusion layers 22. The distance between the second lateral surfaces 22d of the adjacent light diffusion layers 22 and the distance between the lateral surfaces 21c of the adjacent wavelength conversion layers 21 are substantially equal to the distance D2 between the second surfaces 21b of the adjacent wavelength conversion layers 21.

In the light-emitting device 1C according to the second modified example, a lateral surface 22f of the light diffusion layer 22 that is not adjacent to another light diffusion layer 22 and is located at the outermost periphery in a top view does not include a protrusion portion at the upper end and is a flat surface. In a case in which the lateral surface 22f includes a protrusion portion at the upper end, part of the light from the light-emitting element 11 exits in a direction outside the light-emitting device through the protrusion portion of the lateral surface 22f, making the light distribution of the light-emitting device likely to be widened. On the other hand, in a case in which the lateral surface 22f is a flat surface without a protrusion portion at the upper end, light does not escape through the protrusion portion. Thus, the light orientation of the light-emitting device can be narrowed, and the luminance in the front direction of the light-emitting device can be easily improved.

In the light-emitting device 1C, as in the light-emitting device 1B illustrated in FIG. 3, the light-emitting surface 11a of the light-emitting element 11 may be embedded in the wavelength conversion layer 21.

In each of the above-described light-emitting devices 1A to 1C, the difference between the refractive index of the base material (second resin portion) of the wavelength conversion layer 21 and the refractive index of the layer (for example, a sapphire substrate) having the surface (light-emitting surface 11a) that is in contact with the wavelength conversion layer 21 in the light-emitting element 11 is preferably 0.25 or less. This can reduce reflection of light emitted by the light-emitting element 11 at the interface between the light-emitting surface 11a of the light-emitting element 11 and the first surface 21a of the wavelength conversion layer 21 and improve the light extraction efficiency of the light-emitting devices 1A to 1D.

### Method for Manufacturing Light-Emitting Device of First Embodiment

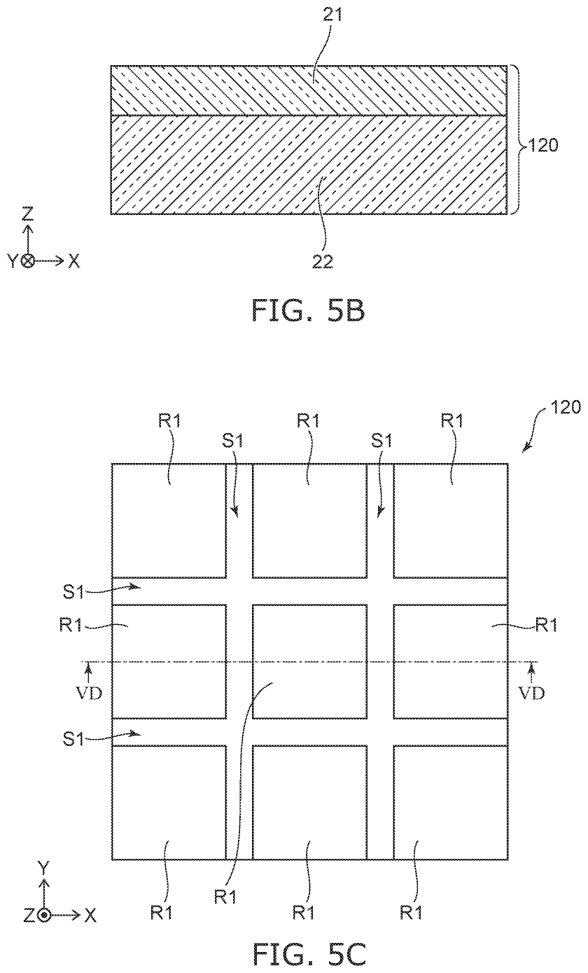

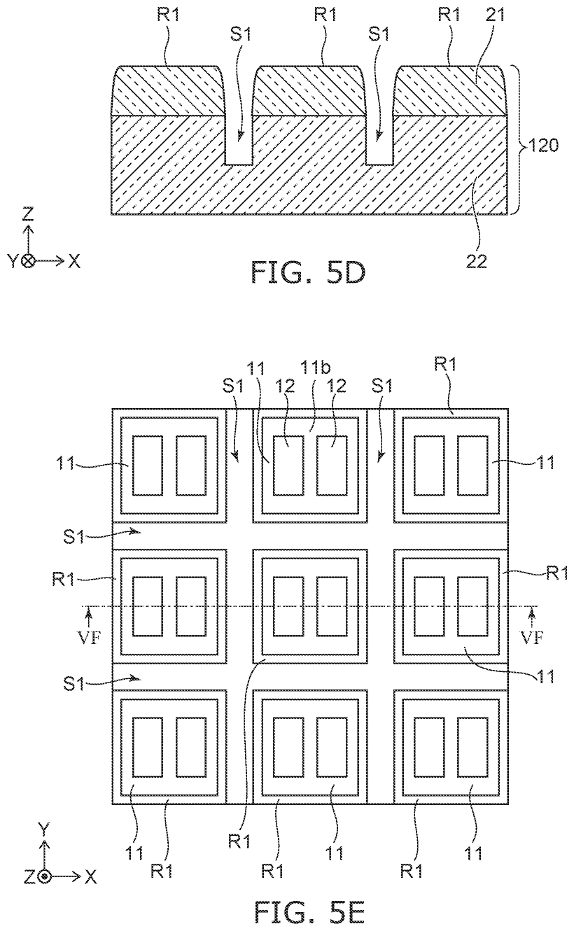

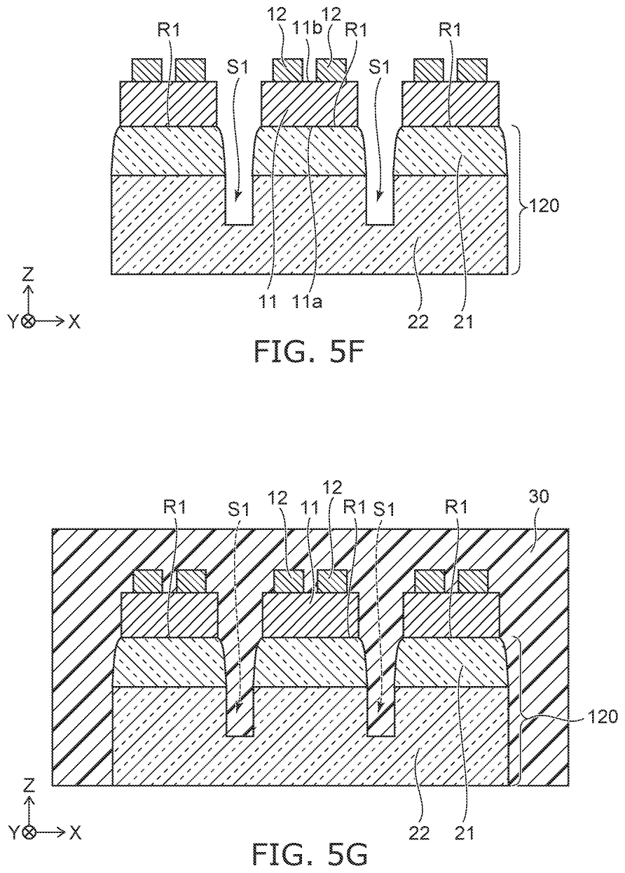

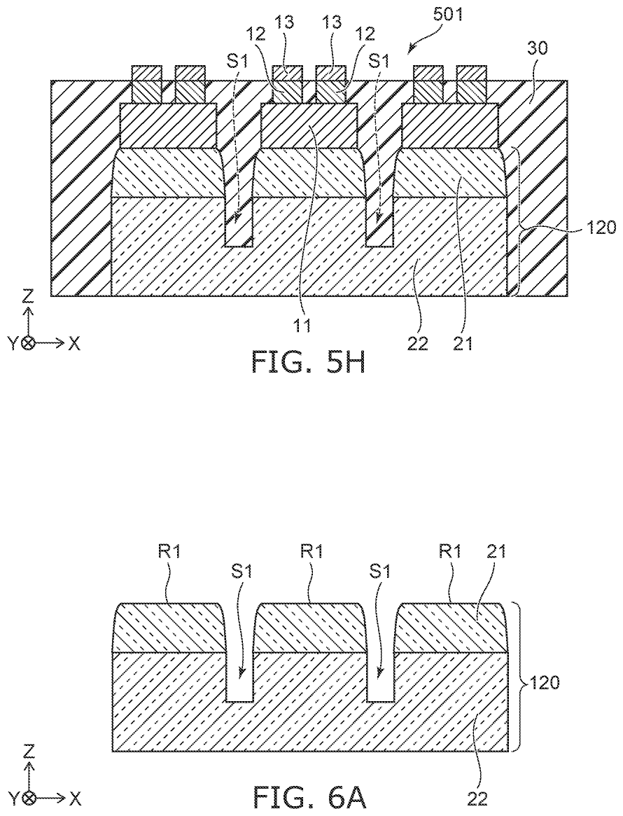

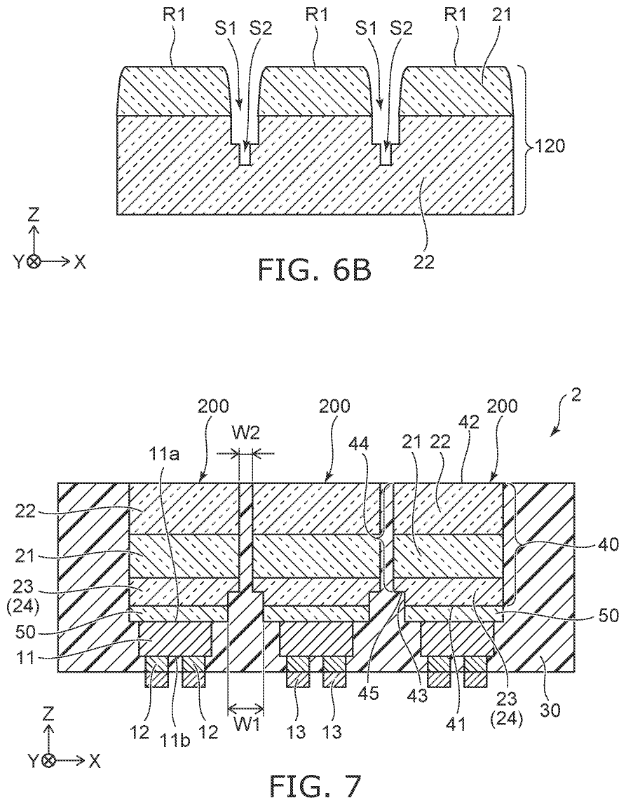

A method for manufacturing the light-emitting device according to the first embodiment will be described below with reference to FIGS. 5A to 6B.

### Process of Providing Light-Transmissive Sheet

The method for manufacturing the light-emitting device according to the first embodiment includes providing a light-transmissive sheet 120 as illustrated in FIGS. 5A and 5B.

The light-transmissive sheet 120 includes the light diffusion layer 22 and the wavelength conversion layer 21 disposed on the light diffusion layer 22. For the light diffusion layer and the wavelength conversion layer, the same terms are used before singulation and after singulation. As described above, the light diffusion layer 22 includes the first resin portion and the light diffusion substance, and the wavelength conversion layer 21 includes the second resin portion and the wavelength conversion substance. In the process of providing the light-transmissive sheet 120, the second resin portion of the wavelength conversion layer 21 is in the stage B state, and the first resin portion of the light diffusion layer 22 is in the stage C state. The stage B state of the second resin portion of the wavelength conversion layer 21 is maintained until the second resin portion is cured in a second heat treatment process described below.

### First Heat Treatment Process

The method for manufacturing the light-emitting device according to the first embodiment includes a first heat treatment process of heat-treating the wavelength conversion layer 21 in the light-transmissive sheet 120 under a first condition. The hardness of the wavelength conversion layer 21 after the first heat treatment process is greater than the hardness of the wavelength conversion layer 21 before the first heat treatment process. The first condition in the first heat treatment process includes a first temperature and a first heating time. For example, the first temperature may be in a range from 80° C. to 130° C., and the first heating time can be in a range from 10 minutes to 120 minutes.

The second resin portion of the wavelength conversion layer 21 after the first heat treatment process is in the stage B state. By performing the first heat treatment process on the light-transmissive sheet 120, it is possible to increase the hardness of the wavelength conversion layer 21 while maintaining a predetermined tack level on the surface of the wavelength conversion layer 21. By increasing the hardness of the wavelength conversion layer 21, a first slit S1 is less likely to be collapsed when the first slit S1 is formed later with a blade or the like. It can be said that the first heat treatment process is a process for adjusting the hardness of the wavelength conversion layer 21. In addition, by performing the first heat treatment process after the process of providing the light-transmissive sheet 120, in other words, after the wavelength conversion layer 21 and the light diffusion layer 22 are joined together, the wavelength conversion layer 21 having a higher tack level than that after the first heat treatment process can be bonded to the light diffusion layer 22, and thus the adhesion between the wavelength conversion layer 21 and the light diffusion layer 22 can be improved. This can suppress peeling or the like at the interface between the wavelength conversion layer 21 and the light diffusion layer 22 when the first slit S1 or the like is formed.

In the present embodiment, for example, the tack level of the second resin portion of the wavelength conversion layer 21 after the first heat treatment process is in a range from 20% to 90% of the tack level of the second resin portion of the wavelength conversion layer 21 before the first heat treatment process.

Process of Dividing Upper Surface of Wavelength Conversion Layer into Plurality of Element Arrangement Regions

The method for manufacturing the light-emitting device according to the first embodiment includes, after the first heat treatment process, a process of forming the first slit S1 in the light-transmissive sheet 120 and dividing the upper surface of the wavelength conversion layer 21 into a plurality of element arrangement regions R1, as illustrated in FIGS. 5C and 5D.

As illustrated in FIG. 5C, the plurality of first slits S1 extend in the first direction X and the second direction Y in a top view. As illustrated in FIG. 5D, the first slit S1 extends from the upper surface of the wavelength conversion layer 21, passes the interface between the wavelength conversion layer 21 and the light diffusion layer 22, and reaches the light diffusion layer 22. The opening of the first slit S1 is located on the upper surface side of the wavelength conversion layer 21, and the bottom portion of the first slit S1 is located in a surface of the light diffusion layer 22. The width of the first slit S1 can be, for example, in a range from 30 μm to 60 μm. At this time, the width between the first slits S1 can be, for example, in a range from 200 μm to 1300 μm. The first slits S1 can be formed with a blade or a laser, for example.

Because the second resin portion of the wavelength conversion layer 21 is in the stage B state in which it is not completely cured, the lateral surface of the wavelength conversion layer 21 defining part of the lateral surface on the opening side of the first slit S1 has a shape defect or part of the first slit S1 is collapsed in some cases due to stress or heat when the first slits S1 are formed with a blade or a laser. According to the present embodiment, it is possible to stabilize the shape of the first slits S1 by increasing the hardness of the wavelength conversion layer 21 in the first heat treatment process before forming the first slits S1.

In the present process, the first slits S1 are formed with a blade or the like while the second resin portion of the wavelength conversion layer 21 is maintained in the stage B state. At this time, when the wavelength conversion layer 21 is cut with a blade or the like, the second resin portion is pulled in the cutting direction of the blade. It is presumed that, due to the effects of the surface tension of the second resin portion or its own weight in this state, an inclined surface is formed at the cut surface and a curved surface is formed at the corner portion of the upper end of the wavelength conversion layer 21. In particular, the lateral surface 21c of the wavelength conversion layer 21 is inclined, and a curved surface is formed at the corner portion formed between the lateral surface 21c and the first surface 21a of the wavelength conversion layer 21.

### Process of Disposing Light-Emitting Elements

The method for manufacturing the light-emitting device according to the first embodiment includes a process of disposing the light-emitting elements 11 respectively in the plurality of element arrangement regions R1 by bringing the light-emitting surfaces 11a of the light-emitting elements 11 into contact with the upper surfaces of the respective wavelength conversion layers 21, as illustrated in FIGS. 5E and 5F. For example, after the electrodes 12 are disposed on the surface 11b on the side opposite to the light-emitting surface 11a of the light-emitting element 11, the light-emitting element 11 is disposed in the element arrangement region R1 together with the electrodes 12.

Here, in a plausible reference example, the light-emitting elements 11 may be disposed on the wavelength conversion layers 21 by supplying a liquid adhesive to the element arrangement regions R1, disposing the light-emitting elements 11 on the adhesive, and then curing the adhesive. In this case, the liquid adhesive may flow into the first slit S1 beyond the element arrangement regions R1. The covering member 30 is disposed in the first slit S1 in a process described below. Thus, when the adhesive is disposed in the first slit S1, the covering member 30 cannot enter into the first slit S1, or in other words, between the adjacent light-transmissive members. Accordingly, the above-described contrast or the like may be reduced in the manufactured light-emitting device.

According to the present embodiment, the light-emitting element 11 is directly bonded to the wavelength conversion layer 21 in the stage B state without using a liquid adhesive. For this reason, unlike in the case of the reference example, no liquid adhesive flows into the first slit S1 and the covering member 30 can be successfully disposed in the first slit S1 in the process described below.

### Second Heat Treatment Process

The method for manufacturing the light-emitting device according to the first embodiment includes, after the process of disposing the light-emitting element 11, a second heat treatment process of heat-treating the second resin portion of the wavelength conversion layer 21 under a second condition to cure the second resin portion of the wavelength conversion layer 21.

By heating in the second heat treatment process, the second resin portion of the wavelength conversion layer 21 is temporarily softened from the stage B state, and then is cured to be in the stage C state. The light diffusion layer 22 already in the stage C state is not softened in the second heat treatment process. Via the second heat treatment process, the light-emitting element 11 is fixed to the wavelength conversion layer 21. Further, the wavelength conversion layer 21 and the light diffusion layer 22 are also fixed to each other. The second condition in the second heat treatment process includes a second temperature and a second heating time. For example, the second temperature can be in a range from 140° C. to 160° C., and the second heating time can be in a range from 100 minutes to 200 minutes.

In the second heat treatment process, the second resin portion of the wavelength conversion layer 21 is temporarily softened. At this time, due to the effects of the surface tension of the second resin portion or its own weight, the inclination of the lateral surface 21c of the wavelength conversion layer 21 is increased and the curved surface of the corner portion formed between the lateral surface 21c and the first surface 21a of the wavelength conversion layer 21 is easily increased.

The shear strength between the light-emitting element 11 and the wavelength conversion layer 21 after the second resin portion of the wavelength conversion layer 21 is cured in the second heat treatment process is, for example, in a range from 400 gf/mm² to 2500 gf/mm². Accordingly, when an uncured covering member is poured into a mold in a subsequent process of disposing the covering member, it is possible to suppress the light-emitting element 11 from peeling off from the wavelength conversion layer 21.

### Process of Disposing Covering Member

The method for manufacturing the light-emitting device according to the first embodiment includes, after the second heat treatment process, a process of disposing the covering member 30 between the plurality of light-emitting elements 11 and in the first slit S1 as illustrated in FIGS. 5G and 5H.

The covering member 30 can be formed with a mold, by using a transfer molding method an injection molding method, a compression molding method, or the like, for example.

In the process of disposing the covering member 30, as illustrated in FIG. 5G, the covering member 30 is disposed covering the lateral surface of the light-transmissive sheet 120, the element arrangement regions R1, the light-emitting elements 11, and the electrodes 12. Thereafter, for example, the covering member 30 is partially removed from the upper surface side using a grinder, and the surfaces of the electrodes 12 are exposed from the covering member 30 as illustrated in FIG. 5H. At this time, part of the electrodes 12 may be removed in addition to the part of the covering member 30. Thereafter, as necessary, the metal films 13 are disposed on the surfaces of the electrodes 12.

After the covering member 30 is disposed, a structure body 501 illustrated in FIG. 5H including the light-transmissive sheet 120, the light-emitting elements 11, the electrodes 12, and the covering member 30 is vertically inverted so that the light diffusion layer 22 is located on the upper surface side, and is transferred onto a support member. Subsequently, part of the light diffusion layer 22 is removed using a grinder, for example. The light diffusion layer 22 is partially removed until the covering member 30 disposed in the first slit S1 is exposed. In this manner, the structure body 501 is divided into the plurality of light-emitting portions 100, as illustrated in FIG. 2. Subsequently, for example, in a case in which a plurality of portions corresponding to the light-emitting device 1A are connected in the XY plane, in a region outside each of the light-emitting portions 100, the covering member 30 is cut using, for example, a blade or a laser to be divided for each of the light-emitting devices 1A.

When the light diffusion layer 22 is partially removed with, for example, a grinder after the structure body 501 is transferred onto the support member, the light diffusion layer 22 is partially removed to the extent that the wavelength conversion layer 21 is not exposed and the light diffusion layer 22 is left on the wavelength conversion layer 21. This may suppress variation in emission color among the light-emitting portions 100 that may be caused by variation in the thickness of the wavelength conversion layer 21 due to removal of part of the wavelength conversion layer 21.

In the above-described first heat treatment process, by increasing the hardness of the second resin portion of the wavelength conversion layer 21, it is possible to suppress shape defects in the lateral surface of the wavelength conversion layer 21 that defines part of the lateral surface on the opening side of the first slit S1, or suppress collapse of part of the first slit S1. In this manner, the covering member 30 is appropriately disposed in the first slit S1 as illustrated in FIG. 5G and the like.

In the first heat treatment process, the second resin portion of the wavelength conversion layer 21 is maintained in a softened state by performing the heat treatment at a temperature in a range from 80° C. to 130° C. for a period of time in a range from 10 minutes to 120 minutes. By performing the second heat treatment process in this state, the light-emitting surfaces 11a of the light-emitting elements 11 are embedded in the wavelength conversion layers 21 when the second resin portion of the wavelength conversion layer 21 melts, and the light-emitting device 1B illustrated in FIG. 3 can be obtained.

The method for manufacturing the light-emitting device 1C illustrated in FIG. 4 further includes, before or after the process of forming the first slit S1, a process of forming a second slit S2 illustrated in FIG. 6B in the light-transmissive sheet 120.

The width of the second slit S2 is narrower than the width of the first slit S1. The width of the second slit S2 can be set in a range from 10 μm to 30 μm, for example. The second slit S2 is located between the plurality of element arrangement regions R1 and overlaps with the first slit S1 in a top view. In the light diffusion layer 22, the bottom portion of the second slit S2 is located at a position deeper than the bottom portion of the first slit S1.

In a case in which the second slit S2 is formed before the process of forming the first slit S1, after the second slit S2 is formed, the first slit S1 is formed at a position overlapping the second slit S2 in a top view such that the bottom portion of the first slit S1 is located at a position shallower than the bottom portion of the second slit S2.

The first slits S1 and the second slits S2 are formed by removing portions of the light-transmissive sheet 120. Because the width of the first slit S1 is greater than the width of the second slit S2, the amount of the light-transmissive sheet 120 removed when forming the first slits S1 may be greater than the amount of the light-transmissive sheet 120 removed when forming the second slits S2. Thus, in a case in which the first slit S1 is formed after the second slit S2 is formed, in some cases, removal waste generated by removing the light-transmissive sheet 120 when the first slit S1 is formed enters the second slit S2 that is narrower in width than the width of the first slit S1 and blocks the opening of the second slit S2.

Thus, it is preferable that the first slit S1 is formed as illustrated in FIG. 6A, and then the second slit S2 is formed as illustrated in FIG. 6B. In this case, after the first slit S1 is formed, the second slit S2 is formed downward from the bottom portion of the first slit S1 at a position overlapping the first slit S1 in a top view. Because the first slit S1 is formed prior to the second slit S2, the removal waste at the time of forming the first slit S1, the amount of which tends to be more than that of the removal waste at the time of forming the second slit S2, does not enter the second slit S2.

The first slit S1 extends through the wavelength conversion layer 21, and the lateral surface of the wavelength conversion layer 21 is defined by the first slit S1 that is wider in width than the width of the second slit S2. Thus, in the second heat treatment process, when the second resin portion of the wavelength conversion layer 21 in the stage B state is temporarily softened, even if the second resin portion flows to the first slit S1 side, because the opening of the first slit S1 is large, the opening of the first slit S1 is less likely to be blocked by the second resin portion.

Light-emitting devices according to a second embodiment and a third embodiment will be described below. In the light-emitting devices according to the second embodiment and the third embodiment, configurations different from the configurations of the light-emitting device according to the first embodiment will be mainly described. The light-emitting devices according to the second embodiment and the third embodiment are different from the light-emitting device according to the first embodiment mainly in that an adhesive resin layer 50 is provided.

### Second Embodiment

FIG. 7 is a schematic cross-sectional view illustrating a light-emitting device 2 according to a second embodiment.

The light-emitting device 2 is provided with a plurality of light-emitting portions 200 and the covering member 30. Each of the light-emitting portions 200 includes the light-emitting element 11, the adhesive resin layer 50, and a light-transmissive member 40.

The covering member 30 is disposed between adjacent light-emitting elements 11 of the plurality of light-emitting elements 11, between adjacent light-transmissive members 40 of the plurality of light-transmissive members 40, and between adjacent adhesive resin layers 50 of the plurality of adhesive resin layers 50 and collectively holds the plurality of light-emitting portions 200. The covering member 30 covers the lateral surface of the light-emitting element 11, the lateral surface of the light-transmissive member 40, and the lateral surface of the adhesive resin layer 50. A second primary surface 42 of the light-transmissive member 40 constituting the light-emitting surface of the light-emitting portion 200 is exposed from the covering member 30.

In a case in which one light-emitting portion 200 emits light and another light-emitting portion 200 adjacent thereto does not emit light, light emitted by the light-emitting portion 200 may be incident on the light-transmissive member 40 of the adjacent light-emitting portion 200 which does not emit light. This may cause light emission from the wavelength conversion substance contained in the light-transmissive member 40 of the light-emitting portion 200 which does not emit light. However, the covering member 30 is provided between adjacent light-emitting elements 11 and between adjacent light-transmissive members 40, to thereby suppress light emission from the wavelength conversion substance contained in the light-transmissive member 40 of the light-emitting portion 200 which does not emit light. As a result, a light-emitting device 2 having a high contrast can be obtained.

In a top view, the covering member 30 is partially disposed in the outer peripheral portion of the light-emitting device 2 in addition to between adjacent light-emitting elements 11 and between adjacent light-transmissive members 40. Specifically, in a top view, the covering member 30 covers a lateral surface, not adjacent to any other light-emitting portion 200, of the outermost one of the light-transmissive members 40. Accordingly, it is possible to reduce light emission to a region outward of the light-transmissive member 40 located at the outermost periphery, and to increase the luminance difference, in the light-emitting surface of the light-emitting device 2, between the upper surface of the light-transmissive member 40 and the upper surface of the covering member 30 located at the outer peripheral portion of the light-emitting device 2, thus making it possible to achieve high contrast.

The adhesive resin layer 50 is disposed on the light-emitting surface 11a of the light-emitting element 11. The light-emitting surface 11a of the light-emitting element 11 is joined in direct contact with the adhesive resin layer 50. A material the same as or similar to the materials given as examples for the second resin portion described above can be used as the material of the adhesive resin layer 50.

For example, the adhesive resin layer 50 and the light-transmissive member 40 have light transmissivity with respect to the light emitted by the light-emitting element 11. The transmittance of the adhesive resin layer 50 and the light-transmissive member 40 with respect to the light emission peak wavelength of the light-emitting element 11 is 70% or greater, preferably 80% or greater, and more preferably 90% or greater.

The light-transmissive member 40 includes the wavelength conversion layer 21 containing the above-described wavelength conversion substance and a light-transmissive intermediate layer 23 containing substantially no wavelength conversion substance. In the light-emitting device 2 according to the second embodiment, the light-transmissive intermediate layer 23 is a light-transmissive layer 24. The light-transmissive member 40 can further include the light diffusion layer 22 disposed on a surface of the wavelength conversion layer 21 on the side opposite to the surface where the light-transmissive layer 24 is disposed. That is, in the light-transmissive member 40, the light-transmissive layer 24 is disposed on the adhesive resin layer 50, the wavelength conversion layer 21 is disposed on the light-transmissive layer 24, and the light diffusion layer 22 is disposed on the wavelength conversion layer 21. The light-transmissive layer 24 includes a third resin portion. A material the same as or similar to the materials given as examples for the second resin portion described above can be used as the material of the third resin portion.

The light-transmissive member 40 has a first primary surface 41, the second primary surface 42, a first lateral surface 43, a second lateral surface 44, and an intermediate surface 45.

The first primary surface 41 is in contact with the adhesive resin layer 50. The second primary surface 42 is located on a side opposite to the first primary surface 41. In the example illustrated in FIG. 7, the second primary surface 42 is the upper surface of the light diffusion layer 22.

The first lateral surface 43 is continuous with the first primary surface 41. In the example illustrated in FIG. 7, the first lateral surface 43 includes only part of the lateral surface of the light-transmissive layer 24.

The second lateral surface 44 is continuous with the second primary surface 42. In the example illustrated in FIG. 7, the second lateral surface 44 includes the lateral surface of the light diffusion layer 22, the lateral surface of the wavelength conversion layer 21, and part of the lateral surface of the light-transmissive layer 24.

The intermediate surface 45 is located between the first lateral surface 43 and the second lateral surface 44, connects the first lateral surface 43 and the second lateral surface 44, and is located in a surface of the light-transmissive intermediate layer 23 (light-transmissive layer 24).

A first width W1 of the covering member 30 disposed between the first lateral surfaces 43 of adjacent ones of the light-transmissive members 40 is greater than the width of a second width W2 of the covering member 30 disposed between the second lateral surfaces 44 of the adjacent light-transmissive members 40. In other words, the distance between the second primary surfaces 42 of the adjacent light-transmissive members 40 is less than the distance between the first lateral surfaces 43 of the adjacent light-transmissive members 40 and the distance between the first primary surfaces 41 of the adjacent light-transmissive members 40.

With such a configuration, it is possible to obtain high contrast as described above via the covering member 30 disposed between the adjacent light-transmissive members 40, reduce the width of the region where the covering member 30 is exposed on the light-emitting surface side of the light-emitting device 2, and reduce luminance unevenness at the light-emitting surface of the light-emitting device 2 in a state where the adjacent light-emitting portions 200 emit light together. The above-described second width W2 is, for example, in a range from 10 μm to 30 μm.

### Method for Manufacturing Light-Emitting Device of Second Embodiment

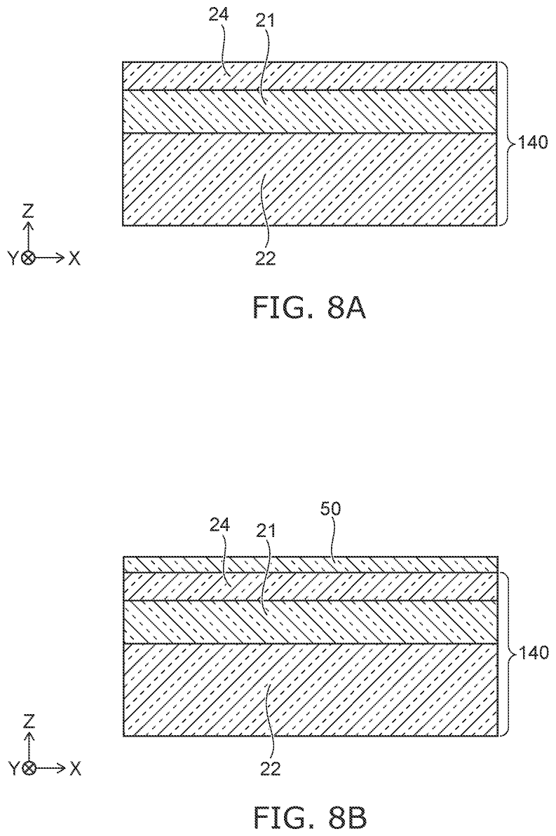

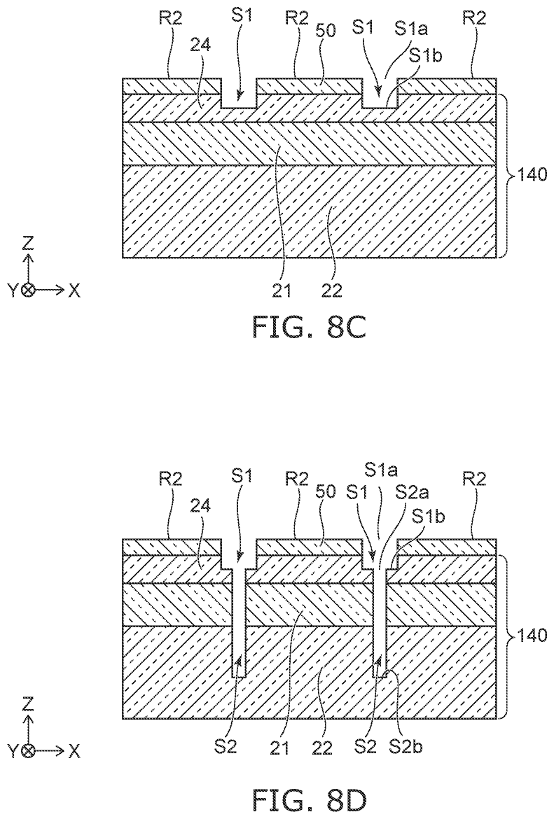

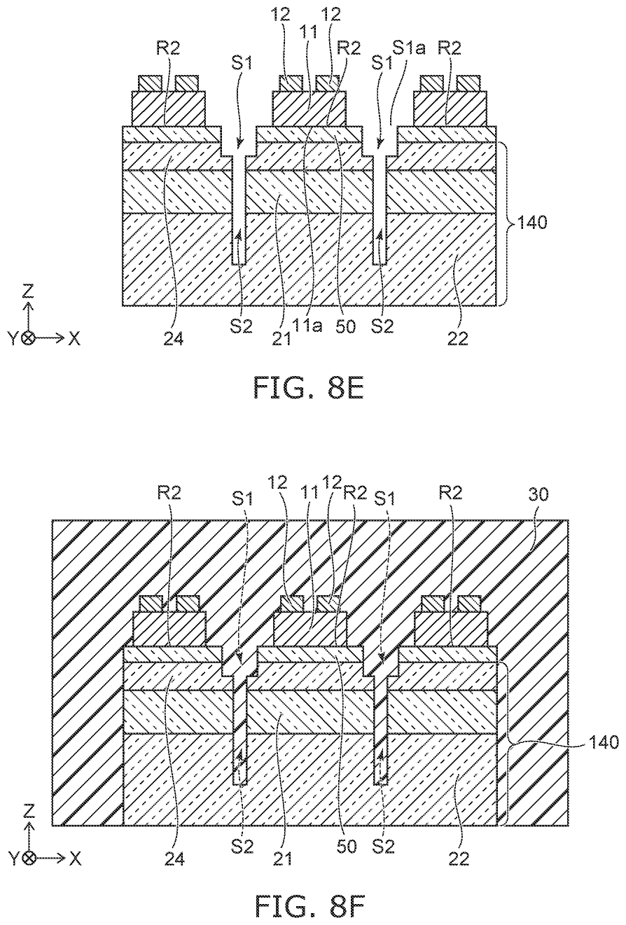

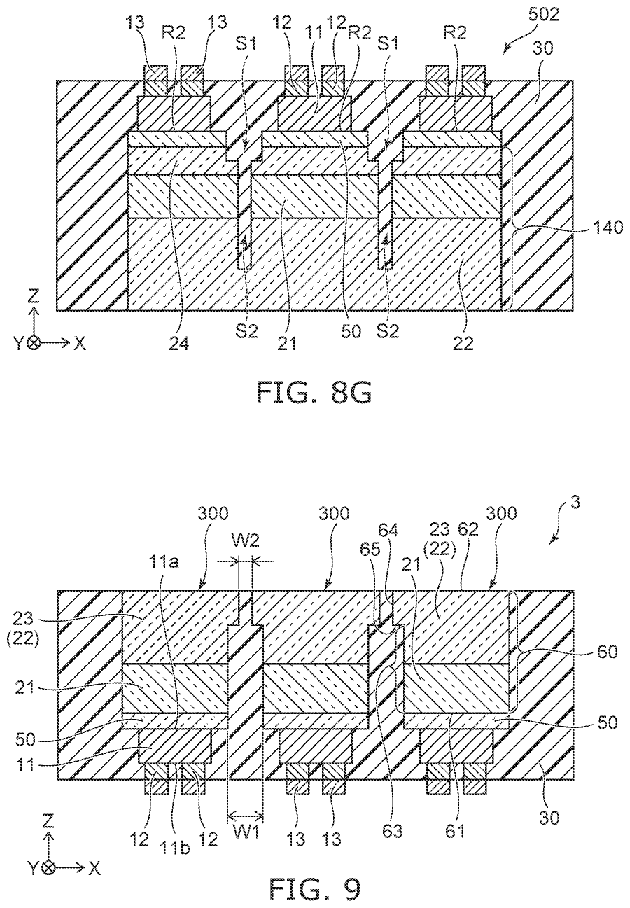

A method for manufacturing the light-emitting device according to the second embodiment will be described with reference to FIGS. 8A to 8G.

### Process of Providing Light-Transmissive Sheet

The method for manufacturing the light-emitting device according to the second embodiment includes a process of providing a light-transmissive sheet 140 as illustrated in FIG. 8A.

The light-transmissive sheet 140 includes the light diffusion layer 22, the wavelength conversion layer 21 disposed on the light diffusion layer 22, and the light-transmissive layer 24 disposed on the wavelength conversion layer 21. For the light diffusion layer and the wavelength conversion layer, the same terms are used before singulation and after singulation. In the process of providing the light-transmissive sheet 140, the first resin portion of the light diffusion layer 22, the second resin portion of the wavelength conversion layer 21, and the third resin portion of the light-transmissive layer 24 are all in the stage C state.

### Process of Disposing Adhesive Resin Layer

The method for manufacturing the light-emitting device according to the second embodiment includes a process of disposing the adhesive resin layer 50 in the stage B state on the upper surface of the light-transmissive layer 24 as illustrated in FIG. 8B. The stage B state of the adhesive resin layer 50 is maintained until the adhesive resin layer 50 is cured in a heat treatment process described below. For the adhesive resin layer, the same term is used before singulation and after singulation.

### Process of Hardness Adjustment of Adhesive Resin Layer

The method for manufacturing the light-emitting device according to the second embodiment may include a process of adjusting the hardness of the adhesive resin layer 50 as necessary after the process of disposing the adhesive resin layer 50. Specifically, in this process, a heat treatment is performed on the adhesive resin layer 50. The hardness of the adhesive resin layer 50 after the heat treatment process is higher than the hardness of the adhesive resin layer 50 before the heat treatment process. The present heat treatment process is performed under the conditions of a range from 80° C. to 130° C. and a range from 10 minutes to 120 minutes.

The adhesive resin layer 50 after the present heat treatment process is in the stage B state. By performing the hardness adjusting process on the adhesive resin layer 50, it is possible to increase the hardness of the adhesive resin layer 50 while maintaining a predetermined tack level on the surface of the adhesive resin layer 50. Increasing the hardness of the adhesive resin layer 50 can suppress, for example, collapse of the first slit S1 when the first slit S1 is formed later with a blade or the like. In addition, by performing the heat treatment process after the process of disposing the adhesive resin layer 50, in other words, after bonding the adhesive resin layer 50 to the light-transmissive sheet 140, the adhesive resin layer 50 having a higher tack level than that after the heat treatment process can be bonded to the light-transmissive sheet 140, so that the adhesion between the adhesive resin layer 50 and the light-transmissive sheet 140 can be improved. This can suppress peeling or the like at the interface between the adhesive resin layer 50 and the light-transmissive sheet 140 when the first slit S1 or the like is formed.

In the present embodiment, for example, the tack level of the adhesive resin layer 50 after the heat treatment process is in a range from 20% to 90% of the tack level of the adhesive resin layer 50 before the heat treatment process.

Process of Dividing Upper Surface of Adhesive Resin Layer into Plurality of Element Arrangement Regions

The method for manufacturing the light-emitting device according to the second embodiment includes a process of forming a slit extending from the upper surface of the adhesive resin layer 50 to the light diffusion layer 22 and dividing the upper surface of the adhesive resin layer 50 into a plurality of element arrangement regions R2.

The process of forming the slit includes a process of forming the first slit S1 as illustrated in FIG. 8C and a process of forming the second slit S2 as illustrated in FIG. 8D. The width of the second slit S2 is less than the width of the first slit S1. The first slit S1 and the second slit S2 can be formed with a blade or a laser, for example.

As illustrated in FIG. 8C, in the process of forming the first slit S1, the first slit S1 is formed having a first opening Sla located at the upper surface of the adhesive resin layer 50 and having a first bottom portion S1b located in a surface of the light-transmissive layer 24.

As illustrated in FIG. 8D, in the process of forming the second slit S2, the second slit S2 is formed having a second opening S2a located at the first bottom portion S1b of the first slit S1 and extending through the wavelength conversion layer 21. A second bottom portion S2b of the second slit S2 is located in the light diffusion layer 22.

Because the first bottom portion S1b of the first slit S1 is located not in the wavelength conversion layer 21 but in the light-transmissive layer 24, variation in depth among the first slits S1 (the positions of the first bottom portions Slb) does not affect variation in thickness (volume) of the wavelength conversion layer 21. This may suppress variation in emission color among the light-emitting portions 200.

### Process of Disposing Light-Emitting Elements

The method for manufacturing the light-emitting device according to the second embodiment includes a process of disposing the light-emitting elements 11 respectively in the plurality of element arrangement regions R2 by bringing the light-emitting surfaces 11a of the light-emitting elements 11 into contact with the upper surfaces of the respective adhesive resin layers 50 as illustrated in FIG. 8E. For example, after the electrodes 12 are disposed on the surface 11b on the side opposite to the light-emitting surface 11a of the light-emitting element 11, the light-emitting element 11 is disposed in the element arrangement region R2 together with the electrodes 12.

According to the second embodiment, the light-emitting element 11 is directly joined to the adhesive resin layer 50 in the stage B state without using a liquid adhesive, as in the first embodiment. For this reason, the covering member 30 can be successfully disposed in the first slit S1 and the second slit S2 in the process described below.

### Heat Treatment Process

The method for manufacturing the light-emitting device according to the second embodiment includes a heat treatment process of heat-treating the adhesive resin layer 50 to cure the adhesive resin layer 50 after the process of disposing the light-emitting element 11.

Via the heating in the heat treatment process, the adhesive resin layer 50 is temporarily softened from the stage B state then being cured to be in the stage C state, and the light-emitting element 11 is fixed to the adhesive resin layer 50. The light-transmissive sheet 140 already in the stage C state is not softened in this heat treatment process.

The conditions in the above-described heat treatment process include a third temperature and a third heating time. For example, the third temperature can be in a range from 140° C. to 160° C., and the third heating time may be in a range from 100 minutes to 200 minutes. The shear strength between the light-emitting element 11 and the adhesive resin layer 50 after the adhesive resin layer 50 is cured in the heat treatment process is, for example, in a range from 400 gf/mm² to 2500 gf/mm². Accordingly, when an uncured covering member is poured into a mold in a subsequent process of disposing the covering member, the light-emitting element 11 is less likely to peel off from the adhesive resin layer 50.

The first slit S1 extends through the adhesive resin layer 50, and the lateral surface of the adhesive resin layer 50 is defined by the first slit S1 that is wider in width than the width of the second slit S2. Thus, in the above-described heat treatment process, when the adhesive resin layer 50 in the stage B state is temporarily softened, even if the adhesive resin layer 50 flows to the first slit S1 side, because the opening of the first slit S1 is large, the first opening of the first slit S1 is less likely to be blocked by the adhesive resin layer 50.

### Process of Disposing Covering Member

The method for manufacturing the light-emitting device according to the second embodiment includes, after the heat treatment process, a process of disposing the covering member 30 between the plurality of light-emitting elements 11, in the first slit S1, and in the second slit S2 as illustrated in FIGS. 8F and 8G.

In the process of disposing the covering member 30, as illustrated in FIG. 8F, the covering member 30 is disposed covering the lateral surface of the light-transmissive sheet 140, the element arrangement regions R2, the light-emitting elements 11, and the electrodes 12. Thereafter, for example, the covering member 30 is partially removed from the upper surface side using a grinder, and the surfaces of the electrodes 12 are exposed from the covering member 30 as illustrated in FIG. 8G. At this time, part of the electrodes 12 may be removed in addition to the covering member 30. Thereafter, as necessary, the metal films 13 are disposed on the surfaces of the electrodes 12.

After the covering member 30 is disposed, a structure body 502 illustrated in FIG. 8G including the light-transmissive sheet 140, the light-emitting elements 11, the electrodes 12, and the covering member 30 is vertically inverted so that the light diffusion layer 22 is located on the upper surface side, and transferred onto a support member. Subsequently, part of the light diffusion layer 22 is removed using a grinder, for example. The light diffusion layer 22 is partially removed until the covering member 30 in the second slit S2 is exposed. In this manner, the structure body 502 is divided into the plurality of light-emitting portions 200, as illustrated in FIG. 7. Subsequently, for example, in a case in which a plurality of portions corresponding to the light-emitting device 2 are connected in the XY plane, in a region outside each of the light-emitting portions 200, the covering member 30 is cut using a blade or a laser, for example, to be divided for each of the light-emitting devices 2.

When the light diffusion layer 22 is partially removed with, for example, a grinder after the structure body 502 is transferred onto the support member, the light diffusion layer 22 is partially removed to the extent that the wavelength conversion layer 21 is not exposed and the light diffusion layer 22 is left on the wavelength conversion layer 21.

This may suppress variation in emission color among the light-emitting portions 200 that may be caused by variation in the thickness of the wavelength conversion layer 21 due to removal of part of the wavelength conversion layer 21.

### Third Embodiment

FIG. 9 is a schematic cross-sectional view of a light-emitting device 3 according to a third embodiment. The light-emitting device 3 according to the third embodiment is different from the light-emitting device 2 according to the second embodiment mainly in that the light-transmissive intermediate layer 23 is the light diffusion layer 22.

The light-emitting device 3 is provided with a plurality of light-emitting portions 300 and the covering member 30. Each of the light-emitting portions 300 includes the light-emitting element 11, the adhesive resin layer 50, and a light-transmissive member 60.

The covering member 30 is disposed between adjacent ones of the plurality of light-emitting elements 11, between adjacent ones of the plurality of light-transmissive members 60, and between adjacent ones of the plurality of adhesive resin layers 50 and collectively holds the plurality of light-emitting portions 300. The covering member 30 covers the lateral surface of the light-emitting element 11, the lateral surface of the light-transmissive member 60, and the lateral surface of the adhesive resin layer 50. A second primary surface 62 of the light-transmissive member 60 constituting the light-emitting surface of the light-emitting portion 300 is exposed from the covering member 30.

In a case in which one light-emitting portion 300 emits light and another light-emitting portion 300 adjacent thereto does not emit light, light emitted by the light-emitting portion 300 may be incident on the light-transmissive member 60 of the adjacent light-emitting portion 300 which does not emit light. This may cause light emission from the wavelength conversion substance contained in the light-transmissive member 60 of the light-emitting portion 300 which does not emit light. However, the covering member 30 is provided between adjacent light-emitting elements 11 and between adjacent light-transmissive members 60, to thereby suppress light emission from the wavelength conversion substance contained in the light-transmissive member 40 of the light-emitting portion 200 which does not emit light. As a result, a light-emitting device 3 having a high contrast can be obtained.

In a top view, the covering member 30 is partially disposed in the outer peripheral portion of the light-emitting device 3 in addition to between adjacent light-emitting elements 11 and between adjacent light-transmissive members 60. Specifically, in a top view, the covering member 30 covers a lateral surface, not adjacent to any other light-emitting portion 300, of the outermost one of the light-transmissive members 60. Accordingly, it is possible to reduce light emission to a region outward of the light-transmissive member 60 located at the outermost periphery, and to increase the luminance difference, in the light-emitting surface of the light-emitting device 3, between the upper surface of the light-transmissive member 60 and the upper surface of the covering member 30 located at the outer peripheral portion of the light-emitting device 3, thus making it possible to achieve high contrast.

In the third embodiment, as in the second embodiment, the adhesive resin layer 50 is disposed on the light-emitting surface 11a of the light-emitting element 11. The light-emitting surface 11a of the light-emitting element 11 is joined in direct contact with the adhesive resin layer 50.

For example, the light-transmissive member 60 has light transmissivity with respect to the light emitted by the light-emitting element 11. The transmittance of the light-transmissive member 60 with respect to the light emission peak wavelength of the light-emitting element 11 is 70% or greater, preferably 80% or greater, and more preferably 90% or greater.

The light-transmissive member 60 includes the wavelength conversion layer 21 containing the above-described wavelength conversion substance and the light-transmissive intermediate layer 23 containing substantially no wavelength conversion substance. In the light-emitting device 3 according to the third embodiment, the light-transmissive intermediate layer 23 is the light diffusion layer 22. In the light-transmissive member 60, the wavelength conversion layer 21 is disposed on the adhesive resin layer 50, and the light diffusion layer 22 is disposed on the wavelength conversion layer 21.

The light-transmissive member 60 has a first primary surface 61, the second primary surface 62, a first lateral surface 63, a second lateral surface 64, and an intermediate surface 65.

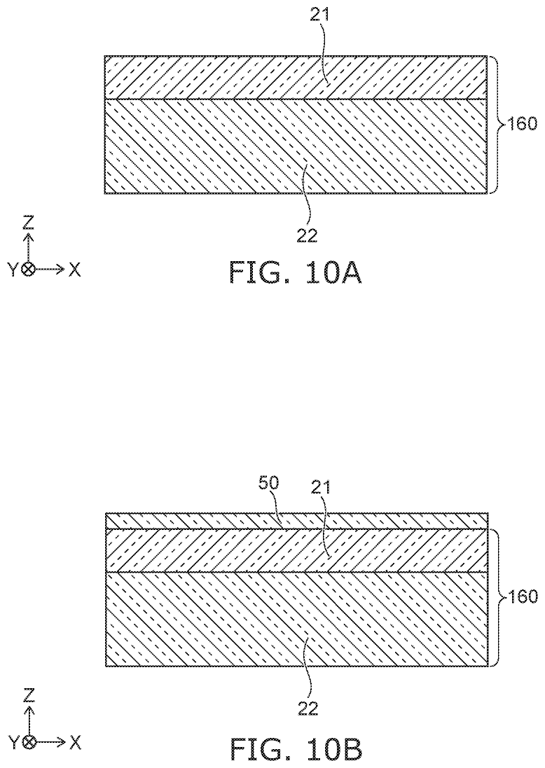

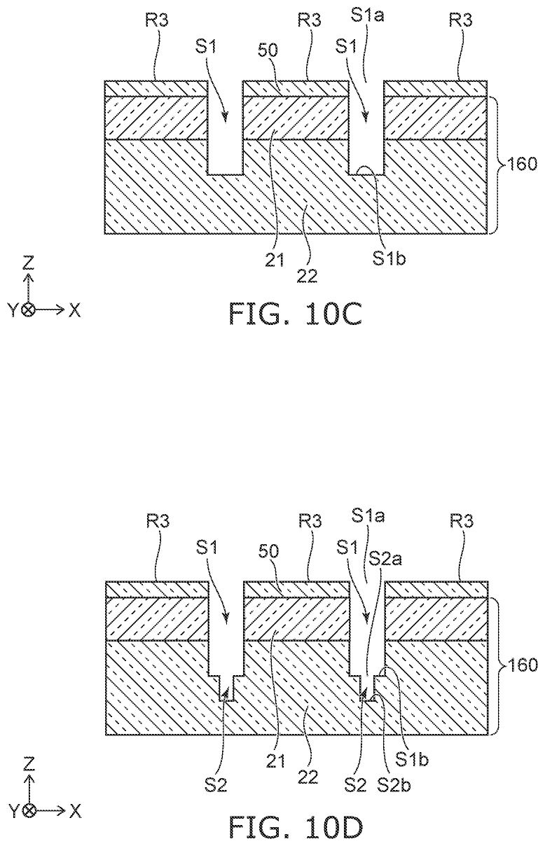

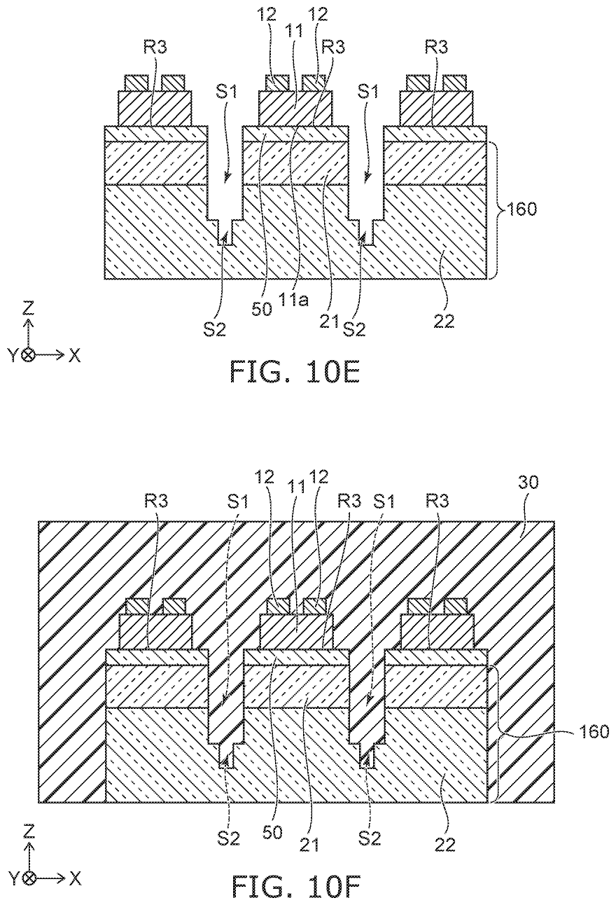

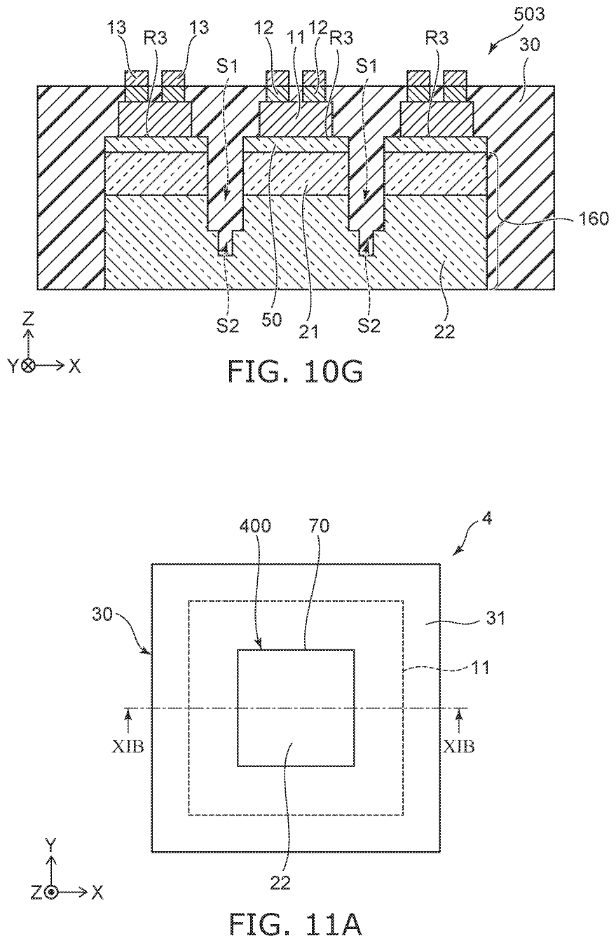

The first primary surface 61 is in contact with the adhesive resin layer 50. The second primary surface 62 is located on a side opposite to the first primary surface 61. In the example illustrated in FIG. 10, the second primary surface 62 is the upper surface of the light-transmissive intermediate layer 23 (light diffusion layer 22).

The first lateral surface 63 is continuous with the first primary surface 61. In the example illustrated in FIG. 9, the first lateral surface 63 includes the lateral surface of the wavelength conversion layer 21 and part of the lateral surface of the light diffusion layer 22.

The second lateral surface 64 is continuous with the second primary surface 62. In the example illustrated in FIG. 9, the second lateral surface 64 includes only part of the lateral surface of the light diffusion layer 22.

The intermediate surface 65 is located between the first lateral surface 63 and the second lateral surface 64, connects the first lateral surface 63 and the second lateral surface 64, and is located in a surface of the light-transmissive intermediate layer 23 (light diffusion layer 22).

The first width W1 of the covering member 30 disposed between the first lateral surfaces 63 of adjacent ones of the plurality of light-transmissive members 60 is greater than the second width W2 of the covering member 30 disposed between the second lateral surfaces 64 of the adjacent light-transmissive members 60. In other words, the distance between the second primary surfaces 62 of the adjacent light-transmissive members 60 is less than the distance between the first lateral surfaces 63 of the adjacent light-transmissive members 60 and the distance between the first primary surfaces 61 of the adjacent light-transmissive members 60.

With such a configuration, it is possible to obtain high contrast as described above via the covering member 30 disposed between the adjacent light-transmissive members 60, reduce the width of the region where the covering member 30 is exposed on the light-emitting surface side of the light-emitting device 3, and reduce luminance unevenness at the light-emitting surface of the light-emitting device 3 in a state where the adjacent light-emitting portions 300 emit light together.

### Method for Manufacturing Light-Emitting Device of Third Embodiment

A method for manufacturing the light-emitting device according to the third embodiment will be described below with reference to FIGS. 10A to 10G.

### Process of Providing Light-Transmissive Sheet

The method for manufacturing the light-emitting device according to the third embodiment includes a process of providing a light-transmissive sheet 160 as illustrated in FIG. 10A.

The light-transmissive sheet 160 includes the light diffusion layer 22 and the wavelength conversion layer 21 disposed on the light diffusion layer 22. For the light diffusion layer and the wavelength conversion layer, the same terms are used before singulation and after singulation. In the process of providing the light-transmissive sheet 160, the first resin portion of the light diffusion layer 22 and the second resin portion of the wavelength conversion layer 21 are all in the stage C state.

### Process of Disposing Adhesive Resin Layer

The method for manufacturing the light-emitting device according to the third embodiment includes a process of disposing the adhesive resin layer 50 in the stage B state on the upper surface of the wavelength conversion layer 21 as illustrated in FIG. 10B. The stage B state of the adhesive resin layer 50 is maintained until the adhesive resin layer 50 is cured in a heat treatment process described below. For the adhesive resin layer, the same term is used before singulation and after singulation.

### Process of Hardness Adjustment of Adhesive Resin Layer

The method for manufacturing the light-emitting device according to the third embodiment may include a process of adjusting the hardness of the adhesive resin layer 50 as necessary after the process of disposing the adhesive resin layer 50. Specifically, in this process, a heat treatment is performed on the adhesive resin layer 50. The hardness of the adhesive resin layer 50 after the heat treatment process is higher than the hardness of the adhesive resin layer 50 before the heat treatment process. The present heat treatment process is performed under the conditions of a range from 80° C. to 130° C. and a range from 10 minutes to 120 minutes.

The adhesive resin layer 50 after the present heat treatment process is in the stage B state. By performing the hardness adjusting process on the adhesive resin layer 50, it is possible to increase the hardness of the adhesive resin layer 50 while maintaining a predetermined tack level on the surface of the adhesive resin layer 50. By increasing the hardness of the adhesive resin layer 50, it is possible to suppress, for example, collapse of the first slit S1 when the first slit S1 is formed later with a blade or the like. In addition, by performing the heat treatment process after the process of disposing the adhesive resin layer 50, in other words, after bonding the adhesive resin layer 50 to the light-transmissive sheet 160, the adhesive resin layer 50 having a higher tack level than that after the heat treatment process can be bonded to the light-transmissive sheet 160, so that the adhesion between the adhesive resin layer 50 and the light-transmissive sheet 160 can be improved. This may suppress peeling or the like at the interface between the adhesive resin layer 50 and the light-transmissive sheet 160 when the first slit S1 or the like is formed.

In the present embodiment, for example, the tack level of the adhesive resin layer 50 after the heat treatment process is in a range from 20% to 90% of the tack level of the adhesive resin layer 50 before the heat treatment process.

Process of Dividing Upper Surface of Adhesive Resin Layer into Plurality of Element Arrangement Regions

The method for manufacturing the light-emitting device according to the third embodiment includes a process of forming a slit extending from the upper surface of the adhesive resin layer 50 to the light diffusion layer 22 and dividing the upper surface of the adhesive resin layer 50 into a plurality of element arrangement regions R3.

The process of forming the slit includes a process of forming the first slit S1 as illustrated in FIG. 10C and a process of forming the second slit S2 as illustrated in FIG. 10D. The width of the second slit S2 is smaller than the width of the first slit S1.

As illustrated in FIG. 10C, in the process of forming the first slit S1, the first slit S1 is formed including the first opening Sia located at the upper surface of the adhesive resin layer 50 and extending through the wavelength conversion layer 21. The first bottom portion S1b of the first slit S1 is located in the light diffusion layer 22.

As illustrated in FIG. 10D, in the process of forming the second slit S2, the second slit S2 is formed including the second opening S2a located at the first bottom portion S1b of the first slit S1 and including a second bottom portion S2b located in the light diffusion layer 22.

Because the first bottom portion S1b of the first slit S1 is located not in the wavelength conversion layer 21 but in the light diffusion layer 22, variation in depth among the first slits S1 (the positions of the first bottom portions Slb) does not affect variation in the thickness (volume) of the wavelength conversion layer 21. This may suppress variation in emission color among the light-emitting portions 200.

### Process of Disposing Light-Emitting Elements

The method for manufacturing the light-emitting device according to the third embodiment includes a process of disposing the light-emitting elements 11 respectively in the plurality of element arrangement regions R3 by bringing the light-emitting surfaces 11a of the light-emitting elements 11 into contact with the upper surfaces of the respective adhesive resin layers 50 as illustrated in FIG. 10E. For example, after the electrodes 12 are disposed on the surface 11b on the side opposite to the light-emitting surface 11a of the light-emitting element 11, the light-emitting element 11 is disposed in the element arrangement region R3 together with the electrodes 12.

According to the third embodiment, the light-emitting element 11 is directly bonded to the adhesive resin layer 50 in the stage B state without using a liquid adhesive, as in the second embodiment. For this reason, the covering member 30 can be successfully disposed in the first slit S1 and the second slit S2 in the process described below.

### Heat Treatment Process

The method for manufacturing the light-emitting device according to the third embodiment includes a heat treatment process of heat-treating the adhesive resin layer 50 to cure the adhesive resin layer 50 after the process of disposing the light-emitting elements 11.

Via the heating in the heat treatment process, the adhesive resin layer 50 is temporarily softened from the stage B state then being cured to be in the stage C state, and the light-emitting element 11 is fixed to the adhesive resin layer 50. The light-transmissive sheet 160 already in the stage C state is not softened in this heat treatment process. The conditions in the heat treatment process of the third embodiment can be the same as the conditions in the heat treatment process of the second embodiment.

The first slit S1 extends through the adhesive resin layer 50, and the lateral surface of the adhesive resin layer 50 is defined by the first slit S1 that is larger in width than the width of the second slit S2. Thus, in the above-described heat treatment process, when the adhesive resin layer 50 in the stage B state is temporarily softened, even if the adhesive resin layer 50 flows to the first slit S1 side, because the opening of the first slit S1 is large, the first opening of the first slit S1 is less likely to be blocked by the adhesive resin layer 50.

### Process of Disposing Covering Member

The method for manufacturing the light-emitting device according to the third embodiment includes, after the heat treatment process, a process of disposing the covering member 30 between the plurality of light-emitting elements 11, in the first slit S1, and in the second slit S2 as illustrated in FIGS. 10F and 10G.

In the process of disposing the covering member 30, as illustrated in FIG. 10F, the covering member 30 is disposed covering the lateral surface of the light-transmissive sheet 160, the element arrangement regions R3, the light-emitting elements 11, and the electrodes 12. Thereafter, for example, the covering member 30 is partially removed from the upper surface side using a grinder, and the surfaces of the electrodes 12 are exposed from the covering member 30 as illustrated in FIG. 10G. At this time, part of the electrodes 12 may be removed in addition to the covering member 30. Thereafter, as necessary, the metal films 13 are disposed on the surfaces of the electrodes 12.

After the covering member 30 is disposed, a structure body 503 illustrated in FIG. 10G including the light-transmissive sheet 160, the light-emitting elements 11, the electrodes 12, and the covering member 30 is vertically inverted so that the light diffusion layer 22 is located on the upper surface side, and transferred onto a support member. Subsequently, part of the light diffusion layer 22 is removed using a grinder, for example. The light diffusion layer 22 is partially removed until the covering member 30 disposed in the second slit S2 is exposed. In this way, the structure body 503 is divided into the plurality of light-emitting portions 300, as illustrated in FIG. 9.

Subsequently, for example, in a case in which a plurality of portions corresponding to the light-emitting device 3 are connected in the XY plane, in a region outside each of the light-emitting portions 300, the covering member 30 is cut using a blade or a laser, for example, to be divided for each of the light-emitting devices 3.

When the light diffusion layer 22 is partially removed with, for example, a grinder after the structure body 503 is transferred onto the support member, the light diffusion layer 22 is not removed until the wavelength conversion layer 21 is exposed, and the light diffusion layer 22 is left on the wavelength conversion layer 21. This may suppress variation in emission color among the light-emitting portions 300 that may be caused by variation in the thickness of the wavelength conversion layer 21 due to removal of part of the wavelength conversion layer 21.

In the light-emitting device 2 according to the second embodiment and the light-emitting device 3 according to the third embodiment, the light-emitting surface 11a of the light-emitting element 11 may be embedded in the adhesive resin layer 50. Accordingly, the contact area between the light-emitting element 11 and the adhesive resin layer 50 can be increased as compared with a configuration in which only the light-emitting surface 11a of the light-emitting element 11 is in contact with the adhesive resin layer 50, and thus the adhesive strength between the light-emitting element 11 and the adhesive resin layer 50 tends to be increased.

### Fourth Embodiment

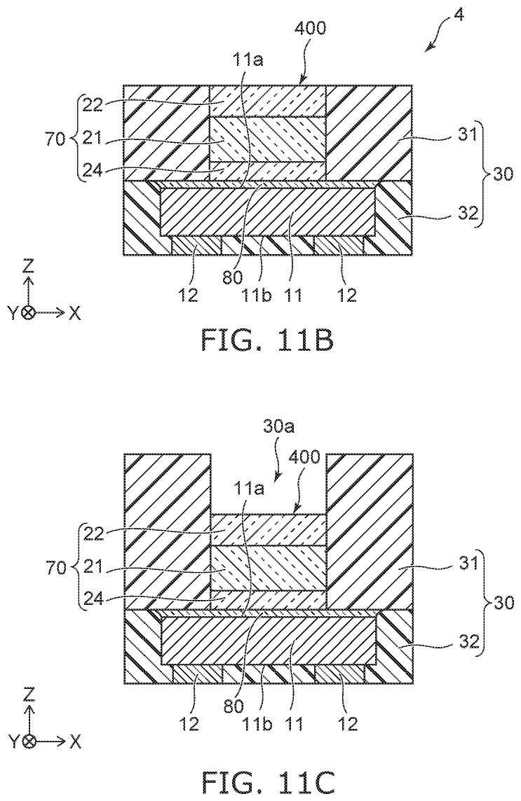

A light-emitting device 4 according to a fourth embodiment will now be described with reference to FIGS. 11A and 11B. The light-emitting device 4 is provided with a light-emitting portion 400 and the covering member 30. In the examples illustrated in FIGS. 11A and 11B, the light-emitting device 4 includes one light-emitting portion 400. The light-emitting device 4 may be provided with a plurality of the light-emitting portions 400. The light-emitting surface of the light-emitting device 4 includes the upper surface of the light-emitting portion 400.

The light-emitting portion 400 includes the light-emitting element 11 and a light-transmissive member 70 disposed over the light-emitting surface 11a of the light-emitting element 11. The light-emitting element 11 has a configuration the same as or similar to those of the above-described embodiments. The light-emitting portion 400 may further include the electrodes 12 disposed on the lower surfaces 11b of the light-emitting element 11.

For example, the light-transmissive member 70 has light transmissivity with respect to the light emitted by the light-emitting element 11. The transmittance of the light-transmissive member 70 with respect to the light emission peak wavelength of the light-emitting element 11 is 70% or greater, preferably 80% or greater, and more preferably 90% or greater. The light-transmissive member 70 includes the wavelength conversion layer 21, the light-transmissive layer 24, and the light diffusion layer 22 described above.

The light-emitting portion 400 can be further provided with an adhesive member 80. The adhesive member 80 fixes together the light-emitting element 11 and the light-transmissive member 70. The adhesive member 80 is disposed on the light-emitting surface 11a of the light-emitting element 11 and continuously covers the lower surface of the light-transmissive member 70 and the lower surface of a first covering member 31 described below. As the material of the adhesive member 80, a light-transmissive resin can be used, and for example, a silicone resin can be used.

The covering member 30 includes the first covering member 31 and a second covering member 32. As the material of the first covering member 31 and the material of the second covering member 32, it is possible to use any of the materials of the covering member 30 given as examples in the embodiments described above.

The first covering member 31 covers the lateral surface of the light-transmissive member 70, the upper surface of the adhesive member 80, and the upper surface of the second covering member 32. A light-emitting surface (upper surface of the light-transmissive member 70) of the light-emitting portion 400 is exposed from the covering member 30. Due to the first covering member 31 being provided, it is possible to reduce light emission to a region outward of the light-transmissive member 70, and to increase the luminance difference, in the light-emitting surface of the light-emitting device 4, between the upper surface of the light-transmissive member 70 and the upper surface of the covering member 30, thus making it possible to achieve high contrast.

The second covering member 32 covers the lateral surface and the lower surface 11b of the light-emitting element 11, and the lateral surface of the adhesive member 80. The second covering member 32 covers the lateral surfaces of the electrode 12. The lower surfaces of the electrodes 12 are exposed from the second covering member 32. Due to the second covering member 32 being provided, it is possible to reduce light emission to a region outward of the lateral surface of the light-emitting element 11 and improve light extraction efficiency of the light-emitting device 4.

According to the fourth embodiment, as illustrated in FIG. 11A, in a top view, an outer edge (indicated by a solid line) of the light-transmissive member 70 is located inward of an outer edge (indicated by a dashed line) of the light-emitting element 11. Accordingly, it is possible to emit narrow-angle light with reduced spread of light as compared with a case in which, in a top view, the outer edge of the light-transmissive member 70 coincides with the outer edge of the light-emitting element 11 or is outward of the outer edge of the light-emitting element 11.

In the light-emitting device 4 illustrated in FIG. 11B, at the upper surface of the light-emitting device 4, the upper surface of the light-emitting portion 400 and the upper surface of the first covering member 31 are flush with each other. The light-emitting device of the present disclosure is not limited to this configuration, and at the upper surface of the light-emitting device 4, the upper surface of the light-emitting portion 400 and the upper surface of the first covering member 31 can be positioned at different heights. For example, as illustrated in FIG. 11C, at the upper surface of the light-emitting device, the upper surface of the first covering member 31 can be positioned at a position higher than the upper surface of the light-emitting portion 400. In the light-emitting device illustrated in FIG. 11C, above the light-emitting portion 400, a recessed portion 30a is formed that is defined by the upper surface of the light-emitting portion 400 and the inner surface of the first covering member 31. The light-emitting device illustrated in FIG. 11C can emit narrow-angle light with further reduced spread of light.

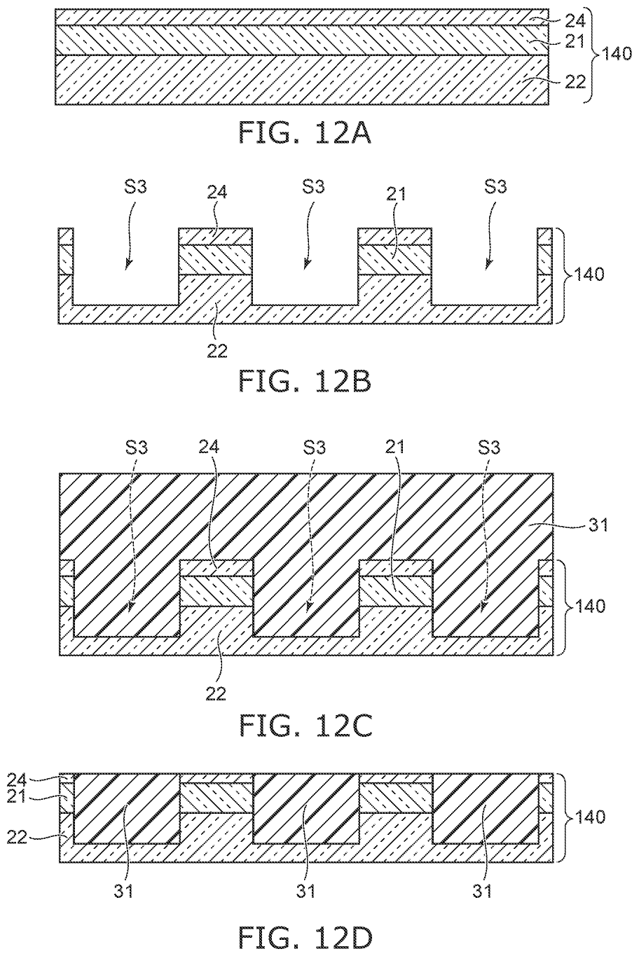

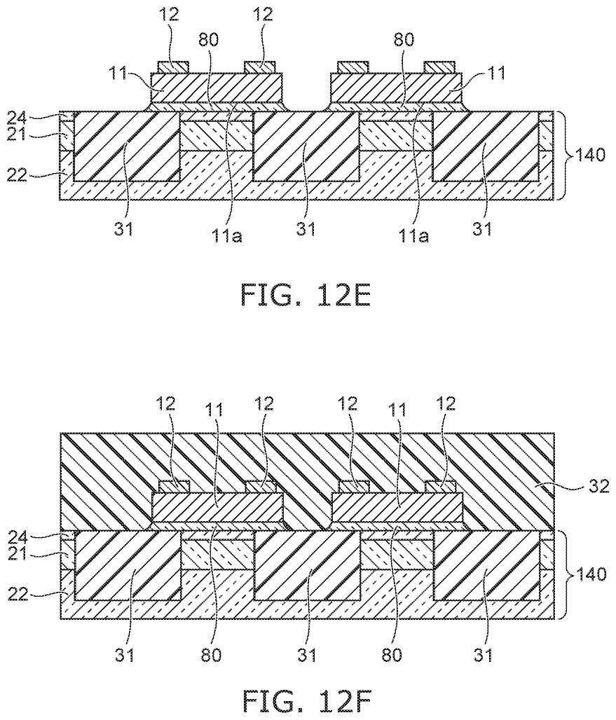

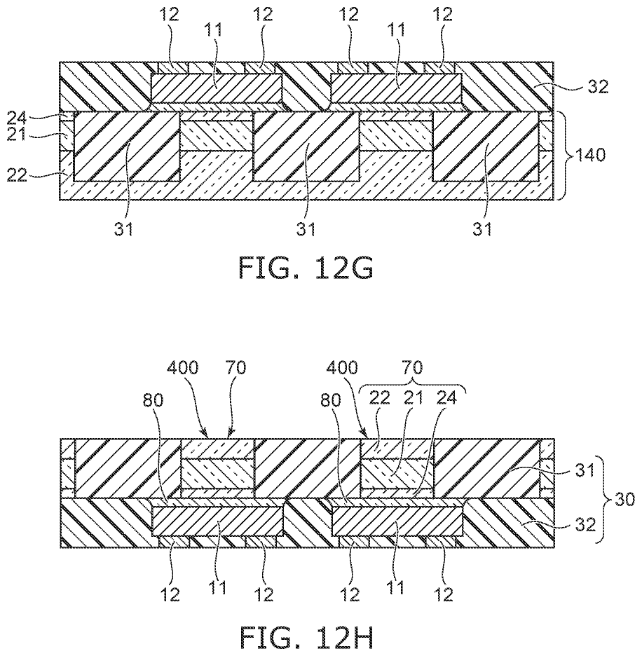

A method for manufacturing the light-emitting device according to the fourth embodiment will be described below with reference to FIGS. 12A to 12H.

The method for manufacturing the light-emitting device according to the fourth embodiment includes a process of providing the light-transmissive sheet 140 as illustrated in FIG. 12A. As described above, the light-transmissive sheet 140 includes the light diffusion layer 22, the wavelength conversion layer 21 disposed on the light diffusion layer 22, and the light-transmissive layer 24 disposed on the wavelength conversion layer 21.

As illustrated in FIG. 12B, the method for manufacturing the light-emitting device according to the fourth embodiment includes a process of forming a plurality of third slits S3 extending from the upper surface of the light-transmissive layer 24, through the wavelength conversion layer 21, and reaching the light diffusion layer 22. The bottom portions of the third slits S3 are located in the light diffusion layer 22. The third slits S3 can be formed with a blade or a laser, for example.

The method for manufacturing the light-emitting device according to the fourth embodiment includes a process of disposing the first covering member 31 in the third slits S3 as illustrated in FIG. 12C. In the process of disposing the first covering member 31, the first covering member 31 is disposed covering the upper surfaces of the light-transmissive layers 24 constituting the upper surface of the light-transmissive sheet 140.

Thereafter, for example, the first covering member 31 is partially removed from the upper surface side using a grinder, and the upper surface of the light-transmissive layer 24 is exposed from the first covering member 31 as illustrated in FIG. 12D. When the first covering member 31 is ground, the light-transmissive layer 24 may also be ground and thinned. Because the wavelength conversion layer 21 is covered with the light-transmissive layer 24 when the first covering member 31 is ground, it is possible to reduce variation in the emission color of the light-emitting portion 400 caused by variation in the thickness of the wavelength conversion layer 21 due to removal of part of the wavelength conversion layer 21.

The method for manufacturing the light-emitting device according to the fourth embodiment includes a process of disposing the light-emitting elements 11 on the upper surfaces of the light-transmissive layers 24 using the adhesive members 80 as illustrated in FIG. 12E. The light-emitting surface 11a of the light-emitting element 11 is bonded to the adhesive member 80. The width of the light-emitting element 11 is greater than the width of the light-transmissive layer 24 located between adjacent ones of the first covering members 31. Thus, part of the light-emitting element 11 is bonded to the upper surface of the first covering member 31 via the adhesive member 80. The adhesive member 80 in an uncured state is supplied to the upper surface of the light-transmissive layer 24 and the upper surface of the first covering member 31 via a dispenser, for example. Subsequently, the adhesive member 80 is cured by heating, for example. Thus, the light-emitting element 11 is joined to the upper surface of the light-transmissive layer 24 and the upper surface of the first covering member 31 via the adhesive member 80. If no first covering member 31 is provided, and the light-emitting element 11 is disposed on the light-transmissive layer 24 with a small width, the light-emitting element 11 may be inclined and the yield rate for the process of disposing the light-emitting element 11 may be likely to be decreased. According to the method for manufacturing the light-emitting device of the fourth embodiment, the first covering member 31 is disposed and the light-emitting element 11 is disposed spanning across the tops of the light-transmissive layer 24 and the first covering member 31, so that it is possible to suppress a decrease in the yield rate or the like in the process of disposing the light-emitting elements 11.

The method for manufacturing the light-emitting device according to the fourth embodiment includes, after the light-emitting elements 11 are disposed, a process of disposing the second covering member 32 on the light-transmissive sheet 140 and the first covering members 31 as illustrated in FIG. 12F.

In the process of disposing the second covering member 32, the second covering member 32 is disposed covering the light-emitting elements 11, the adhesive members 80, and the electrodes 12. Thereafter, for example, the second covering member 32 is partially removed from the upper surface side using a grinder, and the surfaces of the electrodes 12 are exposed from the second covering member 32 as illustrated in FIG. 12G. Thereafter, as necessary, metal films may be disposed on the surfaces of the electrodes 12 as in the embodiments described above.

After the second covering member 32 is disposed, a structure body illustrated in FIG. 12G—including the light-transmissive sheet 140, the light-emitting elements 11, the electrodes 12, the adhesive members 80, the first covering member 31, and the second covering member 32—is vertically inverted so that the light diffusion layer 22 is located on the upper surface side, and transferred onto a support member. Subsequently, part of the light diffusion layer 22 is removed using a grinder, for example. As illustrated in FIG. 12H, the light diffusion layer 22 is partially removed until the first covering member 31 disposed in the third slit S3 is exposed. In this way, the light-transmissive sheet 140 is divided for each of the plurality of light-emitting portions 400. The above-described process of disposing the metal films on the surfaces of the electrodes 12 can be performed after the process of removing part of the light diffusion layer 22. Subsequently, for example, the covering member 30 is cut using a blade or a laser, for example, to separate the light-emitting devices 4.

Embodiments of the present invention have been described above with reference to specific examples. However, the present invention is not limited to these specific examples. All aspects that can be practiced by a person skilled in the art modifying the design as appropriate based on the above-described embodiments of the present invention are also included in the scope of the present invention, as long as they encompass the spirit of the present invention. In addition, in the scope of the concepts of the present invention, a person skilled in the art can conceive of various modified examples and alterations, and those modified examples and alterations will also fall within the scope of the present invention.

What is claimed is:

1. A method for manufacturing a light-emitting device, the method comprising:
providing a light-transmissive sheet comprising:
a light diffusion layer comprising a first resin portion and a light diffusion substance, and
a wavelength conversion layer disposed on the light diffusion layer and comprising a second resin portion in a stage B state and a wavelength conversion substance;
performing a first heat treatment on the wavelength conversion layer under a first condition to increase a hardness of the wavelength conversion layer;
subsequent to the step of performing the first heat treatment, dividing an upper surface of the wavelength conversion layer into a plurality of element arrangement regions by forming a first slit that extends from the upper surface of the wavelength conversion layer, passes an interface between the wavelength conversion layer and the light diffusion layer, and reaches the light diffusion layer;
respectively disposing a plurality of light-emitting elements in the element arrangement regions by respectively bringing light-emitting surfaces of the light-emitting elements into contact with the upper surfaces of the wavelength conversion layers;
subsequent to the step of disposing the light-emitting elements, performing a second heat treatment on the wavelength conversion layers under a second condition to cure the wavelength conversion layers; and
subsequent to the second heat treatment, disposing a covering member between the light-emitting elements and in the first slit.

2. The method for manufacturing a light-emitting device, according to claim 1, further comprising:
before or subsequent to the step of forming the first slit, forming a second slit having a width smaller than a width of the first slit, the second slit being located between the element arrangement regions in a top view.

3. The method for manufacturing a light-emitting device, according to claim 2, wherein:
subsequent to the step of forming the first slit, the second slit is formed in a bottom portion of the first slit.

4. The method for manufacturing a light-emitting device, according to claim 1, wherein:
a width of the first slit is in a range from 30 μm to 60 μm.

5. The method for manufacturing a light-emitting device, according to claim 2, wherein:
the width of the second slit is in a range from 10 μm to 30 μm.

6. The method for manufacturing a light-emitting device, according to claim 1, wherein:
the first condition comprises a first temperature and a first heating time,
the first temperature is in a range from 80° C. to 130° C., and
the first heating time is in a range from 10 minutes to 120 minutes.

7. The method for manufacturing a light-emitting device, according to claim 1, wherein:
the second condition comprises a second temperature and a second heating time,
the second temperature is in a range from 140° C. to 160° C., and
the second heating time is in a range from 100 minutes to 200 minutes.

8. The method for manufacturing a light-emitting device, according to claim 1, wherein:
in the step of disposing the light-emitting elements, the light-emitting surface of at least one of the light-emitting elements is embedded in the wavelength conversion layer.

9. The method for manufacturing a light-emitting device, according to claim 1, wherein:
a tack level of the second resin portion subsequent to the step of performing the first heat treatment is in a range from 20% to 90% of a tack level of the second resin portion before the step of performing the first heat treatment.

10. The method for manufacturing a light-emitting device, according to claim 1, wherein:
in the second heat treatment, a shear strength between the light-emitting element and the wavelength conversion layer subsequent to the step of performing the second heat treatment is in a range from 400 gf/mm² to 2500 gf/mm².

11. The method for manufacturing a light-emitting device, according to claim 1, wherein:
a difference between a refractive index of the second resin portion of the wavelength conversion layer and a refractive index of a layer including the light-emitting surface of the light-emitting element is 0.25 or less.

12. A light-emitting device comprising:
a plurality of light-emitting portions, each comprising:
a light-emitting element, and
a light-transmissive member comprising a wavelength conversion layer directly disposed on the light-emitting element; and
a covering member disposed between adjacent ones of the light-emitting elements and between adjacent ones of the light-transmissive members, wherein:
the wavelength conversion layer has a first surface where the light-emitting element is disposed, a second surface located on a side opposite to the first surface, and a lateral surface connecting the first surface and the second surface,
the lateral surface is inclined to define an obtuse angle with the first surface and an acute angle with the second surface, and
a corner portion formed between the first surface and the lateral surface is a curved surface.

13. The light-emitting device according to claim 12, wherein:
the light-transmissive member further comprises a light diffusion layer disposed on the second surface of the wavelength conversion layer, and
a distance between upper surfaces of adjacent ones of the light diffusion layers is smaller than a distance between the second surfaces of adjacent ones of the wavelength conversion layers.

14. The light-emitting device according to claim 13, wherein:
a distance between the upper surfaces of adjacent ones of the light diffusion layers is in a range from 10 μm to 30 μm.

15. The light-emitting device according to claim 12, wherein:
a difference between a refractive index of a base material of the wavelength conversion layer and a refractive index of a layer including a surface of the light-emitting element that is in contact with the wavelength conversion layer is 0.25 or less.

16. The light-emitting device according to claim 12, wherein:
a surface of the light-emitting element that is in contact with the wavelength conversion layer is embedded in the wavelength conversion layer.

17. A method for manufacturing a light-emitting device, the method comprising:
providing a light-transmissive sheet that comprises:
a light diffusion layer comprising a first resin portion and a light diffusion substance, and
a wavelength conversion layer disposed on the light diffusion layer and comprising a second resin portion and a wavelength conversion substance;
disposing an adhesive resin layer in a stage B state on an upper surface of the wavelength conversion layer;
dividing an upper surface of the adhesive resin layer into a plurality of element arrangement regions by forming a slit that extends from an upper surface of the adhesive resin layer and reaches the light diffusion layer;
respectively disposing a plurality of light-emitting elements in the element arrangement regions by respectively bringing light-emitting surfaces of the light-emitting elements into contact with the upper surfaces of the adhesive resin layers;
subsequent to the step of disposing the light-emitting elements, performing a heat treatment on the adhesive resin layers to cure the adhesive resin layers; and
subsequent to the step of performing the heat treatment, disposing a covering member between the light-emitting elements and in the slit, wherein:
the step of forming the slit comprises:
forming a first slit including a first opening at the upper surface of the adhesive resin layer and a first bottom portion, and
forming a second slit including a second opening at the first bottom portion, wherein the second slit has a width smaller than a width of the first slit, and the second slit extends into the light diffusion layer.

18. The method for manufacturing a light-emitting device, according to claim 17, wherein:
the light-transmissive sheet further comprises a light-transmissive layer disposed on the wavelength conversion layer on a side opposite to a side of the wavelength conversion layer where the light diffusion layer is disposed, the light-transmissive layer comprising a third resin portion,
in the step of disposing the adhesive resin layer, the adhesive resin layer is disposed on an upper surface of the light-transmissive layer,
in the step of forming the first slit, the first slit is formed in such a manner that the first bottom portion of the first slit is located in the light-transmissive layer, and
in the step of forming the second slit, the second slit extends through the wavelength conversion layer.

19. The method for manufacturing the light-emitting device, according to claim 17, wherein:
in the step of forming the first slit, the first slit extends through the wavelength conversion layer.

20. A light-emitting device comprising:
a plurality of light-emitting portions, each comprising:
a light-emitting element,
an adhesive resin layer disposed on the light-emitting element, and
a light-transmissive member disposed on the adhesive resin layer, the light-transmissive member comprising:
a wavelength conversion layer comprising a wavelength conversion substance, and
a light-transmissive intermediate layer not comprising a wavelength conversion substance; and
a covering member disposed between adjacent ones of the light-emitting elements and between adjacent ones of the light-transmissive members, wherein:
the light-transmissive member has a first primary surface that is in contact with the adhesive resin layer, a second primary surface located on a side opposite to the first primary surface, a first lateral surface continuous with the first primary surface, a second lateral surface continuous with the second primary surface, and an intermediate surface located in a surface of the light-transmissive intermediate layer and connecting the first lateral surface and the second lateral surface, and
a width of a portion of the covering member disposed between the first lateral surfaces of the adjacent ones of the light-transmissive members is greater than a width of a portion of the covering member disposed between the second lateral surfaces of the adjacent ones of the light-transmissive members.

21. The light-emitting device according to claim 20, wherein:
the light-transmissive member comprises the light-transmissive intermediate layer disposed on the adhesive resin layer, the wavelength conversion layer disposed on the light-transmissive intermediate layer, and a light diffusion layer disposed on the wavelength conversion layer.

22. The light-emitting device according to claim 20, wherein:
the light-transmissive member comprises the wavelength conversion layer disposed on the adhesive resin layer and the light-transmissive intermediate layer disposed on the wavelength conversion layer, and
the light-transmissive intermediate layer is a light diffusion layer.
